(19) United States
(12) Patent Application Publication
(10) Pub. No.: US 2025/0024666 A1
(43) Pub. Date: Jan. 16, 2025

(54) SEMICONDUCTOR MEMORY DEVICE

(71) Applicant: SAMSUNG ELECTRONICS CO., LTD., SUWON-SI (KR)

(72) Inventors: Yanghee Lee, Suwon-si (KR); Hyukmin Kim, Suwon-si (KR); Donghoon Kwon, Suwon-si (KR); Jonghyuk Park, Suwon-si (KR)

(21) Appl. No.: 18/740,166

(22) Filed: Jun. 11, 2024

(30) Foreign Application Priority Data
Jul. 14, 2023 (KR) 10-2023-0092036

(51) Int. Cl. H10B 12/00

(52) U.S. Cl. CPC H10B 12/50; H10B 12/315; H10B 12/482; H10B 12/488

(57) ABSTRACT

A semiconductor memory device includes a substrate including a memory cell region in which active regions are defined, a peripheral region in which a logic active region is defined, and a boundary region including a region isolation trench between the memory cell region and the peripheral region, a boundary structure including a boundary isolation layer, a region isolation structure, and a region isolation filling layer sequentially disposed in the region isolation trench, and a word line extending across the active regions, wherein among the active regions, an active region located at an outermost part of the memory cell region and the region isolation structure are spaced apart from each other by a first width, and the word line extends by an extension length less than the first width from an edge of the active region located at the outermost part of the memory cell region towards the region isolation structure.

### CROSS-REFERENCE TO RELATED APPLICATION

This application is based on and claims priority under 35 U.S.C. § 119 to Korean Patent Application No. 10-2023-0092036, filed on Jul. 14, 2023, in the Korean Intellectual Property Office, the disclosure of which is incorporated by reference herein in its entirety.

### TECHNICAL FIELD

The inventive concept relates to a semiconductor memory device, and more particularly, to a semiconductor memory device having a memory cell region and a peripheral region.

### DESCRIPTION OF RELATED ART

In accordance with the development of the electronics industry and the demands of users, electronic devices are becoming more compact and lightweight. Accordingly, a degree of integration of semiconductor memory devices used in electronic devices has also been improved. As the degree of integration of the semiconductor memory devices increases, a decrease in design rules for components of the semiconductor memory devices decrease and an increase in aspect ratios may be needed, which may increase the process difficulty for forming the components of the semiconductor memory devices.

### SUMMARY

The inventive concept provides a semiconductor memory device having an improved degree of integration.

According to an aspect of the inventive concept, there is provided a semiconductor memory device including a substrate including a memory cell region in which a plurality of active regions are defined, a peripheral region in which at least one logic active region is defined, and a boundary region including a region isolation trench between the memory cell region and the peripheral region, a boundary structure including a boundary isolation layer, a region isolation structure, and a region isolation filling layer sequentially disposed in the region isolation trench, and a word line extending across the plurality of active regions in the memory cell region, wherein among the plurality of active regions, an active region located at an outermost part of the memory cell region and the region isolation structure are spaced apart from each other by a first width, and the word line extends by an extension length less than the first width from the active region located at the outermost part of the memory cell region towards the region isolation structure.

According to another aspect of the inventive concept, there is provided a semiconductor memory device including a substrate including a memory cell region in which a plurality of active regions are defined, a peripheral region in which at least one logic active region is defined, and a boundary region including a region isolation trench between the memory cell region and the peripheral region, a boundary structure including a boundary isolation layer, a region isolation structure, and a region isolation filling layer sequentially disposed in the region isolation trench, and surrounding the memory cell region in a plan view, a plurality of word lines extending in a first horizontal direction across the plurality of active regions in the memory cell region, a plurality of bit lines respectively disposed on the plurality of active regions and extending in a second horizontal direction crossing the first horizontal direction, and a gate line disposed on the at least one logic active region, wherein the region isolation structure and the plurality of word lines are spaced apart from each other in the first horizontal direction and the second horizontal direction.

According to another aspect of the inventive concept, there is provided a semiconductor memory device including a substrate including a memory cell region in which a plurality of active regions are defined, a peripheral region in which at least one logic active region is defined, and a boundary region including a region isolation trench between the memory cell region and the peripheral region, a boundary structure including a boundary isolation layer, a region isolation structure, and a region isolation filling layer sequentially disposed in the region isolation trench and surrounding the memory cell region in a plan view, the boundary isolation layer including oxide and having a U-shaped vertical cross-section, the region isolation structure including nitride and disposed on the boundary isolation layer to have a U-shaped vertical cross-section between the memory cell region and the peripheral region, and the region isolation filling layer including oxide and disposed on the region isolation structure, a plurality of word lines extending in a first horizontal direction across the plurality of active regions in the memory cell region, a plurality of bit lines respectively disposed on the plurality of active regions and extending in a second horizontal direction substantially orthogonal to the first horizontal direction, a gate line disposed on the at least one logic active region, a plurality of buried contacts respectively disposed between the plurality of bit lines and connected to the plurality of active regions, a plurality of landing pads respectively disposed on the plurality of buried contacts between the plurality of bit lines and extending onto the plurality of bit lines, and a plurality of capacitor structures including a plurality of lower electrodes respectively connected to the plurality of landing pads, an upper electrode, and a capacitor dielectric layer disposed between the plurality of lower electrodes and the upper electrode, wherein the region isolation structure and the plurality of word lines are spaced apart from each other in a plan view.

### BRIEF DESCRIPTION OF THE DRAWINGS

Embodiments will be more clearly understood from the following detailed description taken in conjunction with the accompanying drawings in which:

FIG. 1 is a diagram illustrating a semiconductor memory device according to some embodiments;

FIG. 2 is a schematic plan layout for explaining a semiconductor memory device according to some embodiments;

FIG. 3A and FIG. 3B are schematic plan layouts for explaining components of a semiconductor memory device according to some embodiments;

FIG. 4A to FIG. 4E, FIG. 5A to FIG. 5E, FIG. 6A to FIG. 6E, FIG. 7A to FIG. 7E, FIG. 8A to FIG. 8E, FIG. 9A to FIG. 9E, FIG. 10A to FIG. 10E, FIG. 11A to FIG. 11E, FIG. 12A to FIG. 12E, FIG. 13A to FIG. 13E, FIG. 14A to 14D, and FIG. 15A to FIG. 15D are cross-sectional views illustrating a method of manufacturing a semiconductor memory device, according to some embodiments; and

FIG. 16A to FIG. 16E are cross-sectional views illustrating a semiconductor memory device, according to some embodiments.

### DETAILED DESCRIPTION

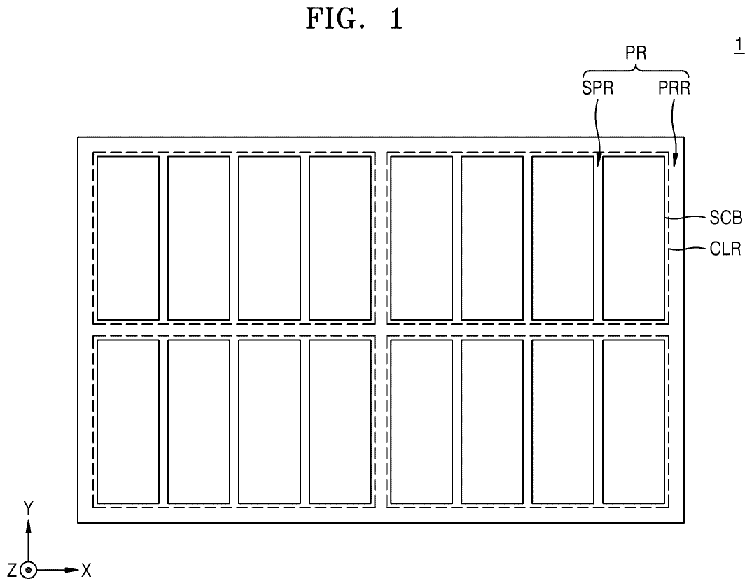

FIG. 1 is a diagram illustrating a semiconductor memory device 1 according to some embodiments.

Referring to FIG. 1, the semiconductor memory device 1 may include a cell region CLR and a main peripheral region PRR. Memory cells may be disposed in the cell region CLR. The main peripheral region PRR may surround the cell region CLR. The cell region CLR may include sub-peripheral regions SPR. The sub-peripheral regions SPR may divide cell blocks SCB from each other. A plurality of memory cells may be disposed in the cell blocks SCB. A peripheral region PR may include the main peripheral region PRR and the sub-peripheral regions SPR. That is, the peripheral region PR may surround the cell blocks SCB.

Logic cells may be disposed in the main peripheral region PRR and the sub-peripheral regions SPR. The logic cells may be configured for inputting/outputting electrical signals to the memory cells. In some embodiments, the main peripheral region PRR may be referred to as a peripheral circuit region and the sub-peripheral region SPR may be referred to as a core circuit region. That is, the peripheral region PR may include a peripheral circuit region and a core circuit region. In some embodiments, at least a part of the sub-peripheral region SPR may be provided as a space for dividing the cell blocks SCB.

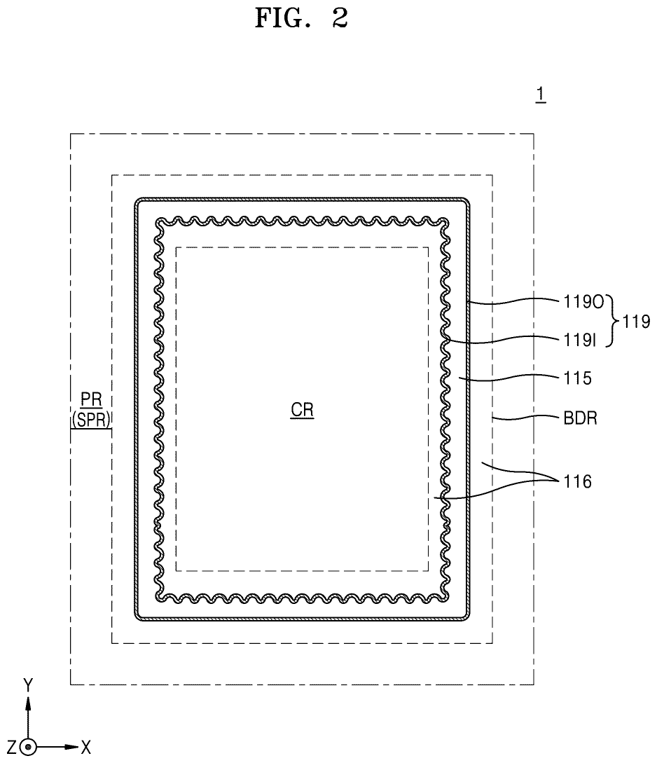

FIG. 2 is a schematic plan layout for explaining the semiconductor memory device 1 according to an embodiment.

Referring to FIG. 2, the semiconductor memory device 1 may include a memory cell region CR, a peripheral region PR, and a boundary region BDR. The boundary region BDR may be disposed between the memory cell region CR and the peripheral region PR. The boundary region BDR may extend between the memory cell region CR and the peripheral region PR. The boundary region BDR may surround the memory cell region CR in a plan view. For example, the boundary region BDR may extend along an edge of the memory cell region CR to surround the memory cell region CR. The boundary region BDR may extend along an edge of the memory cell region CR to completely surround the memory cell region CR. The sub-peripheral region SPR of the peripheral region PR may surround the boundary region BDR and the memory cell region CR.

In some embodiments, the memory cell region CR may be the cell block SCB shown in FIG. 1. In some embodiments, the memory cell region CR may be a part of the cell block SCB. For example, the cell block SCB may include a plurality of memory cell regions CR.

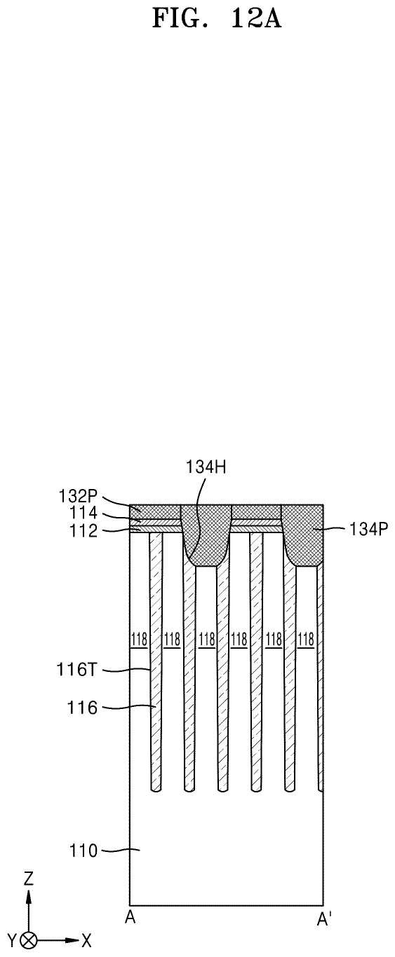

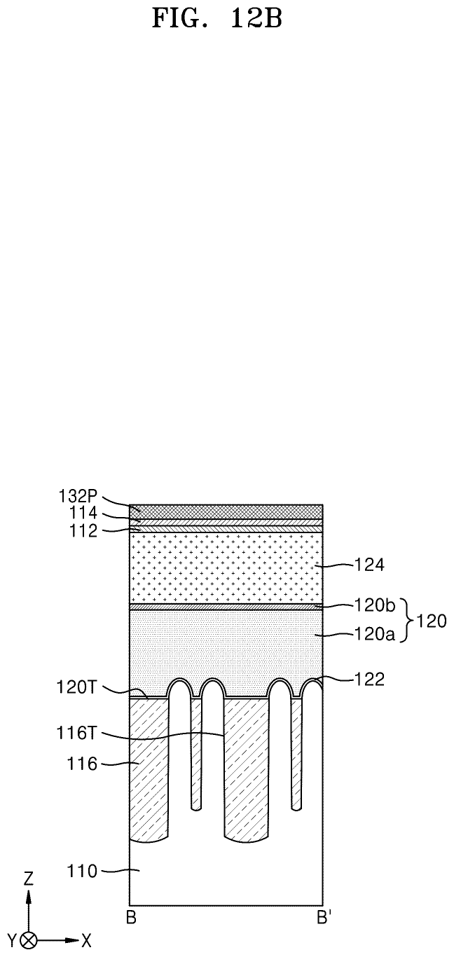

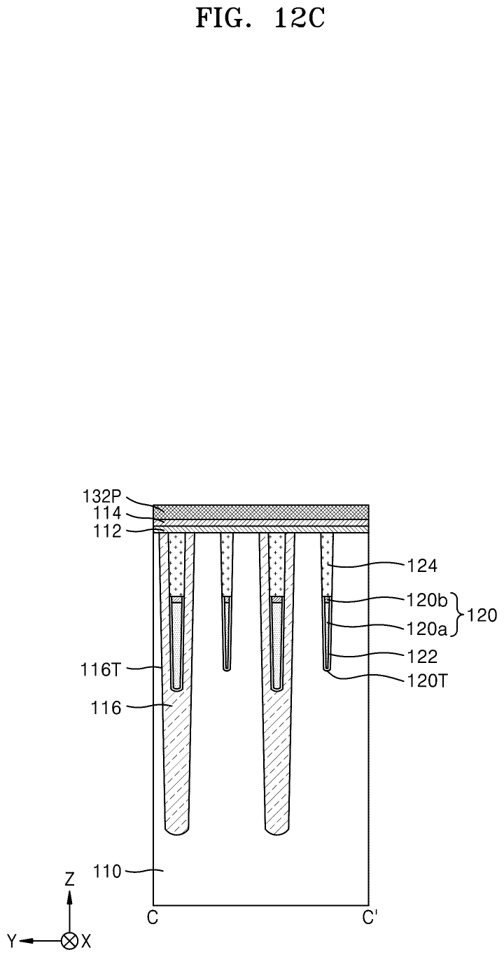

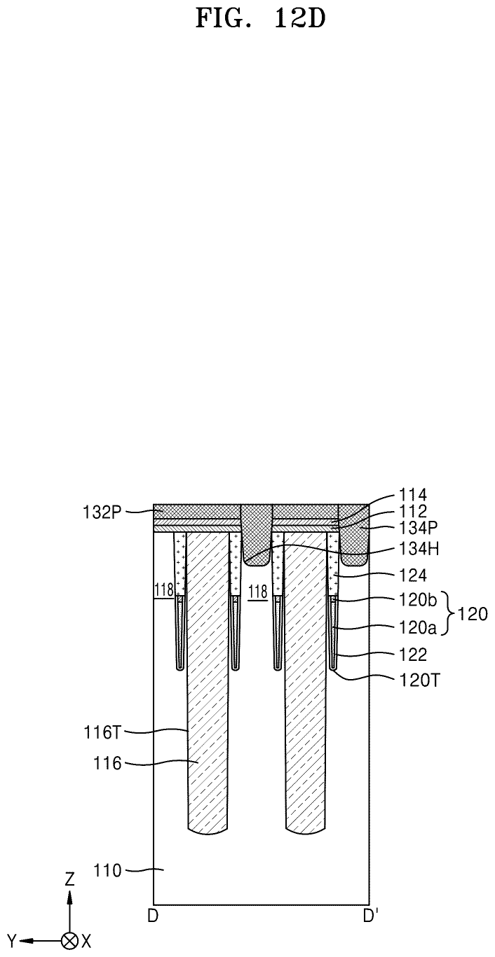

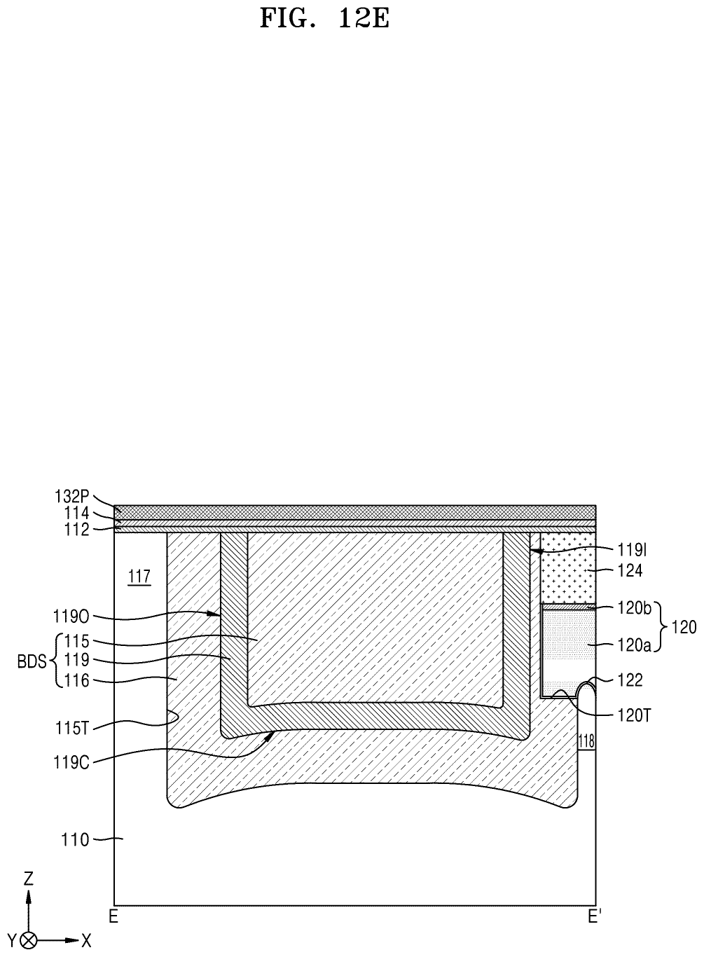

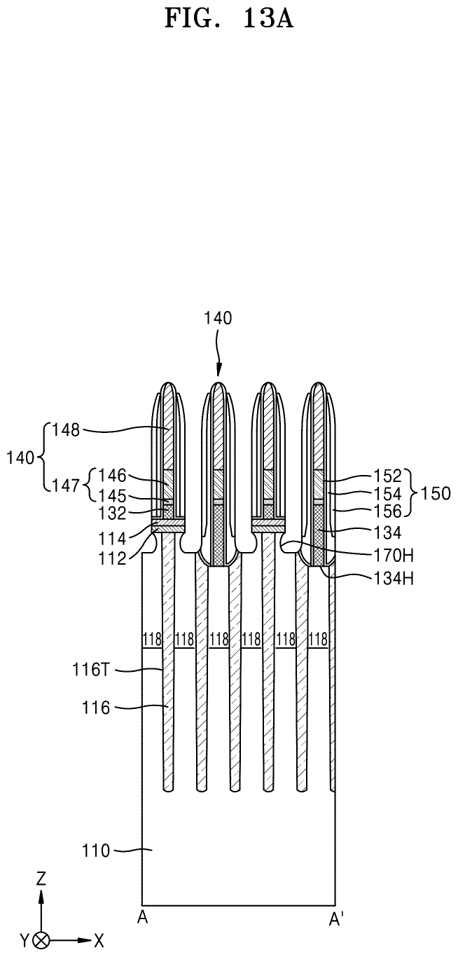

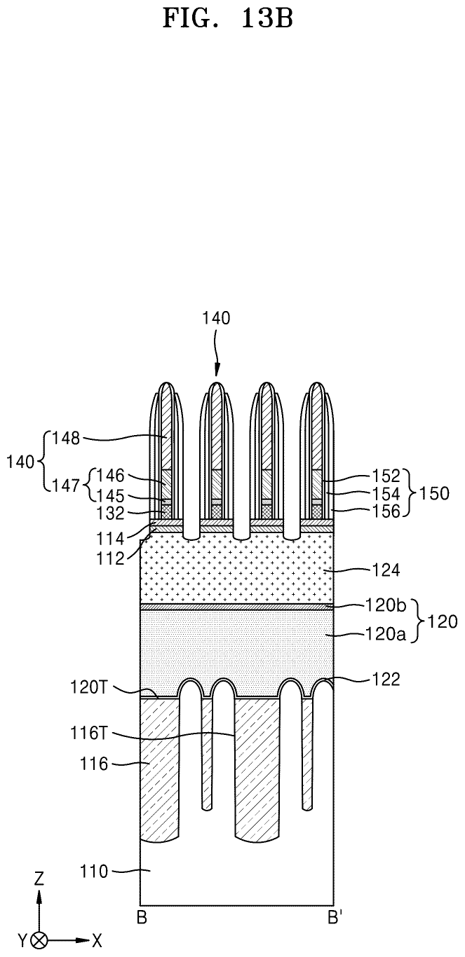

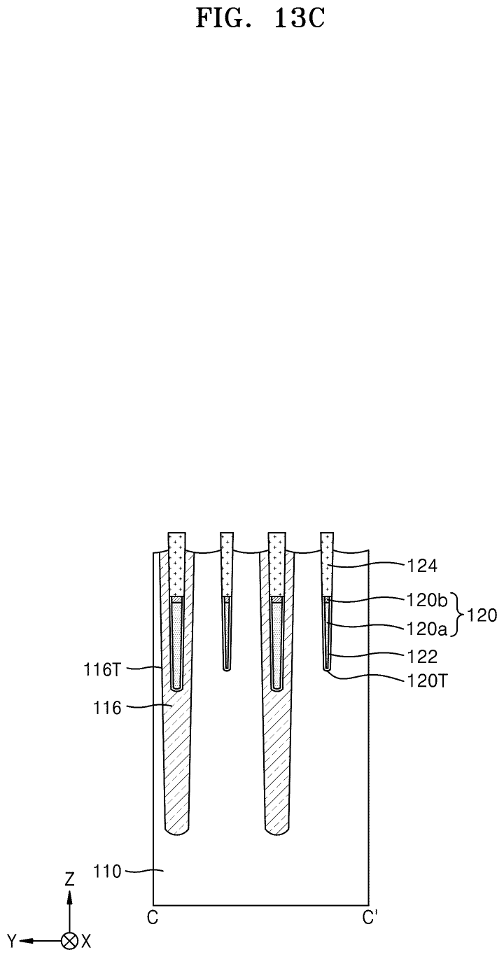

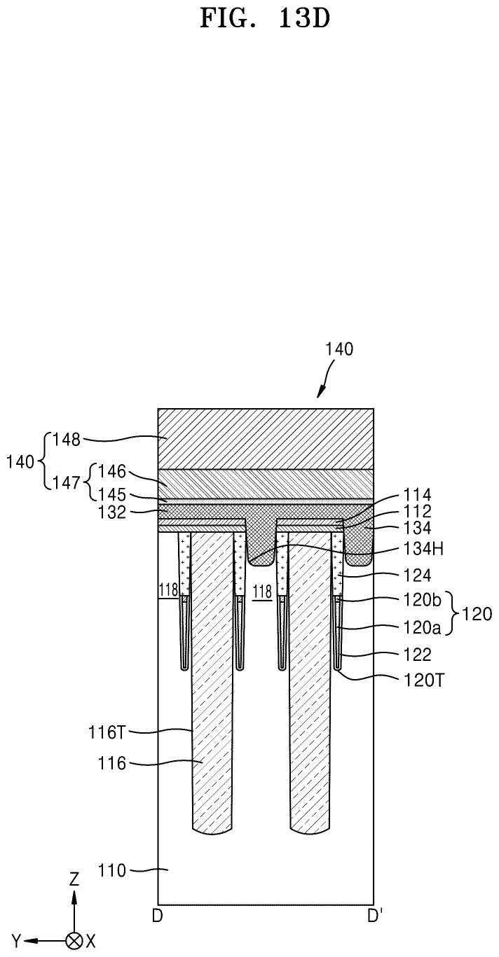

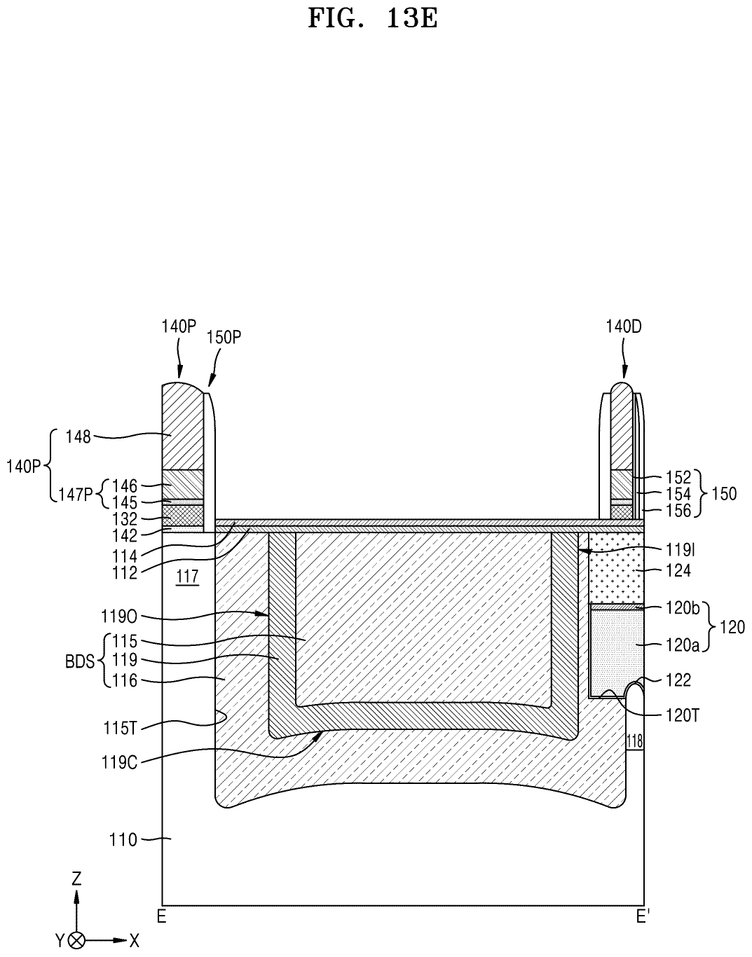

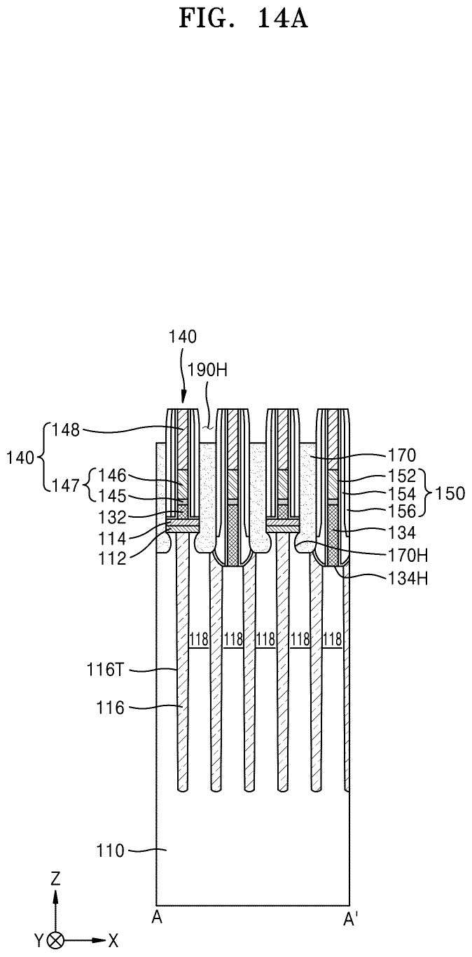

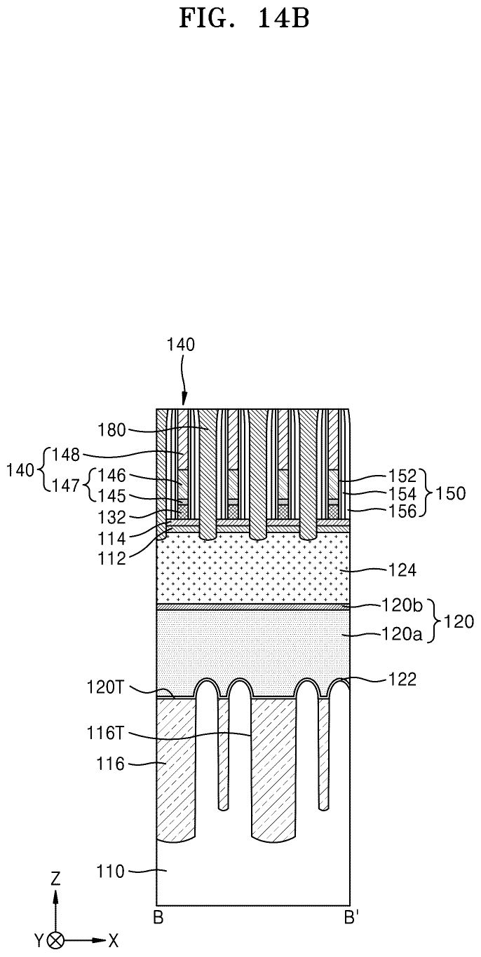

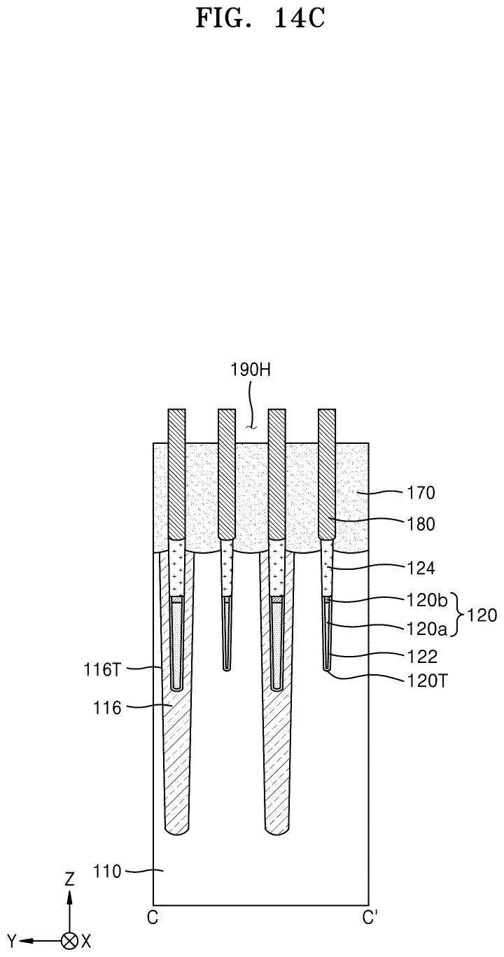

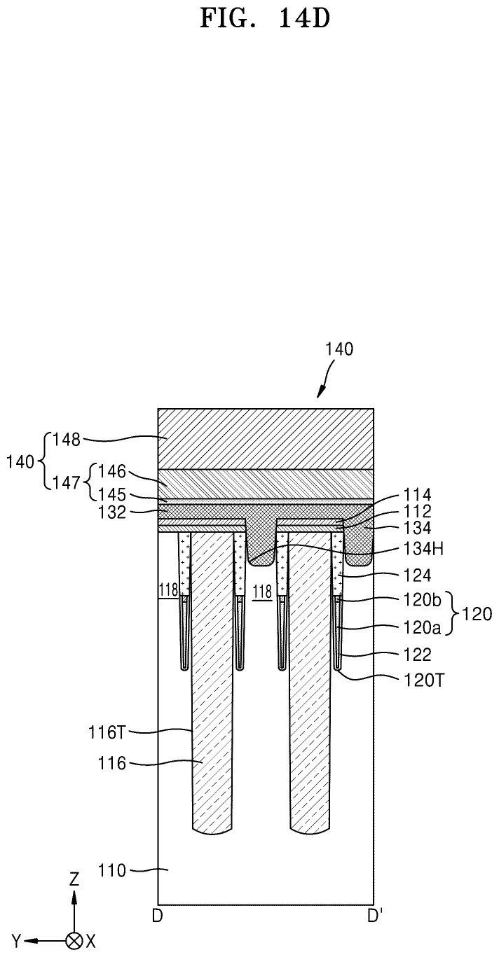

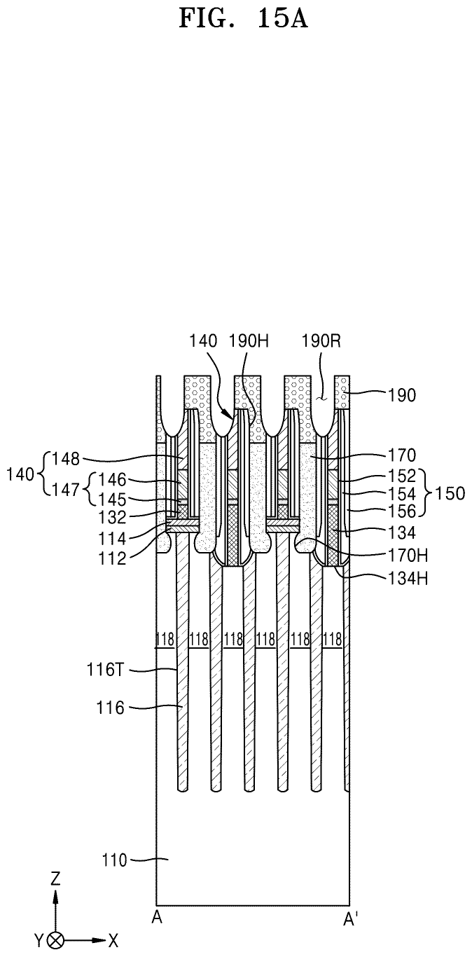

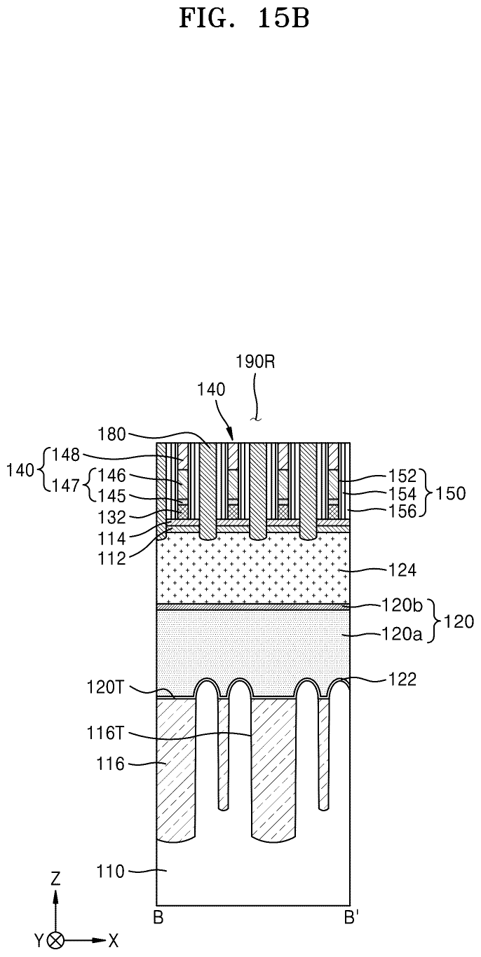

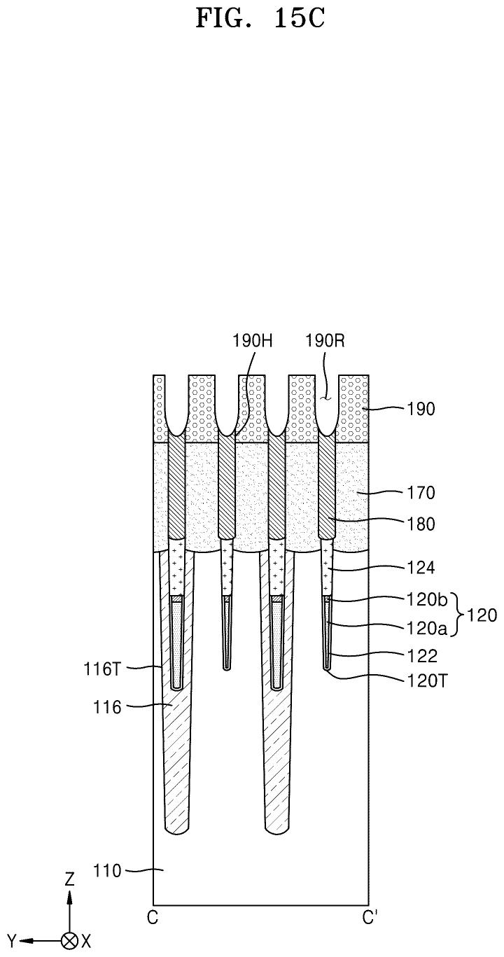

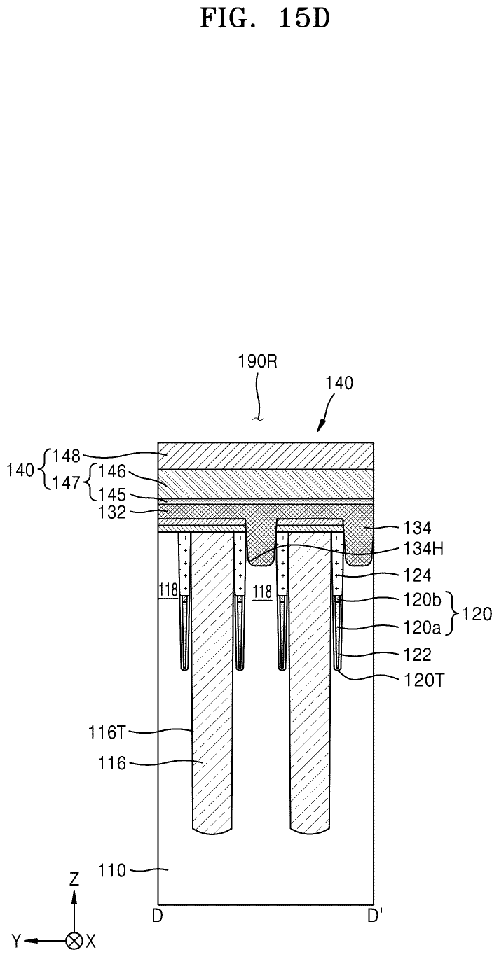

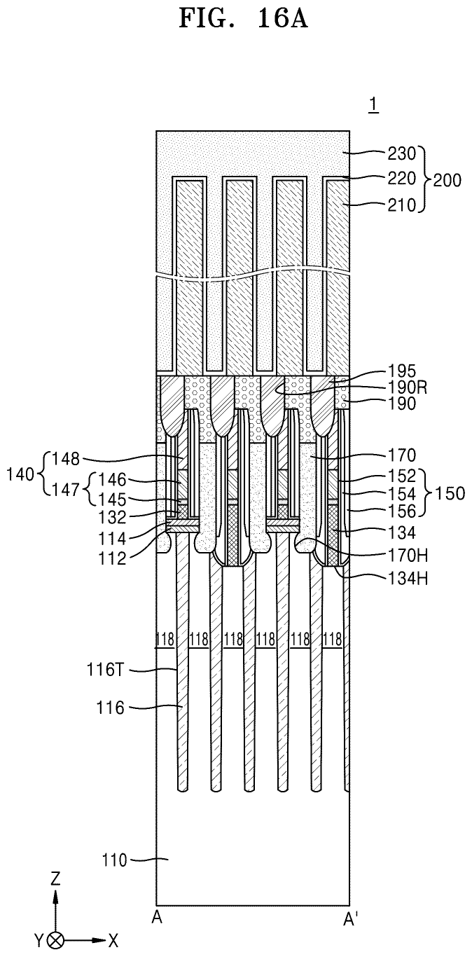

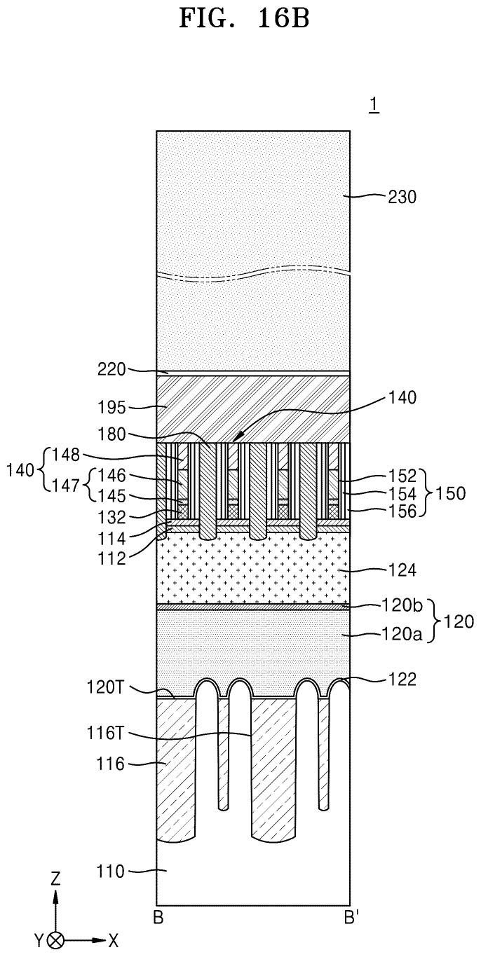

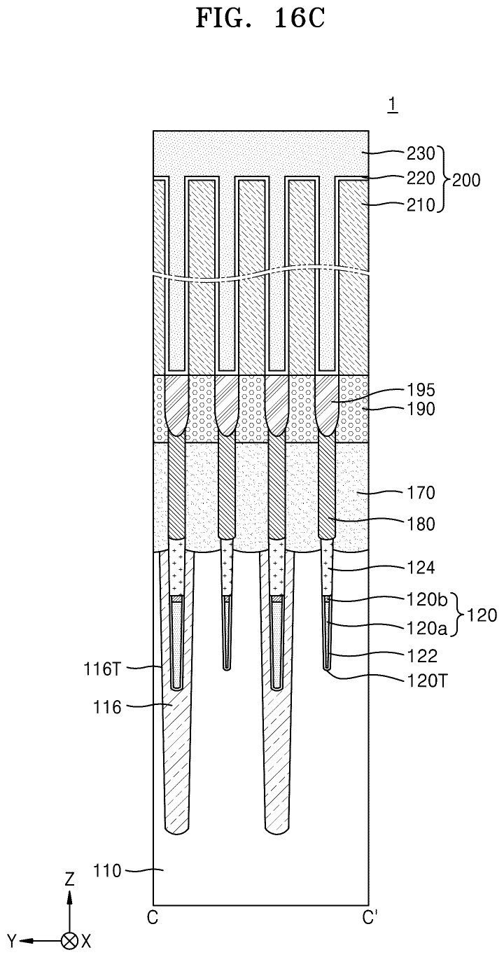

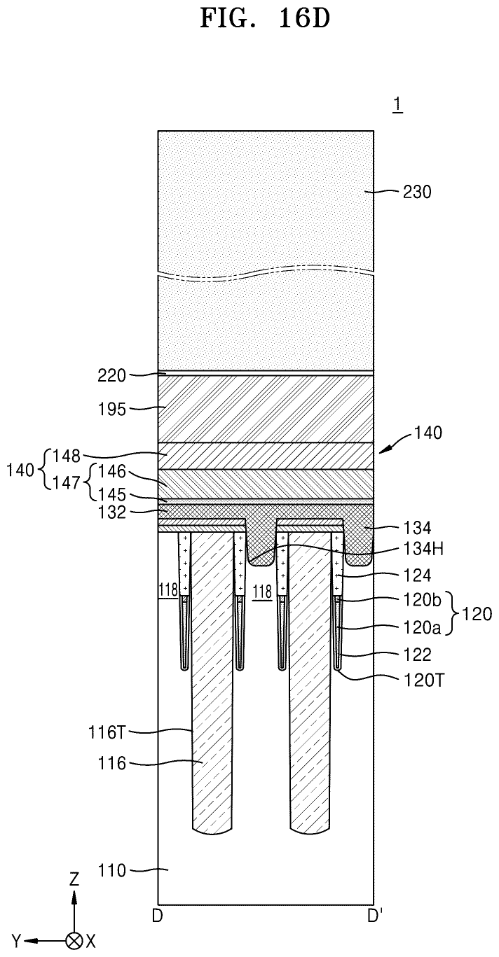

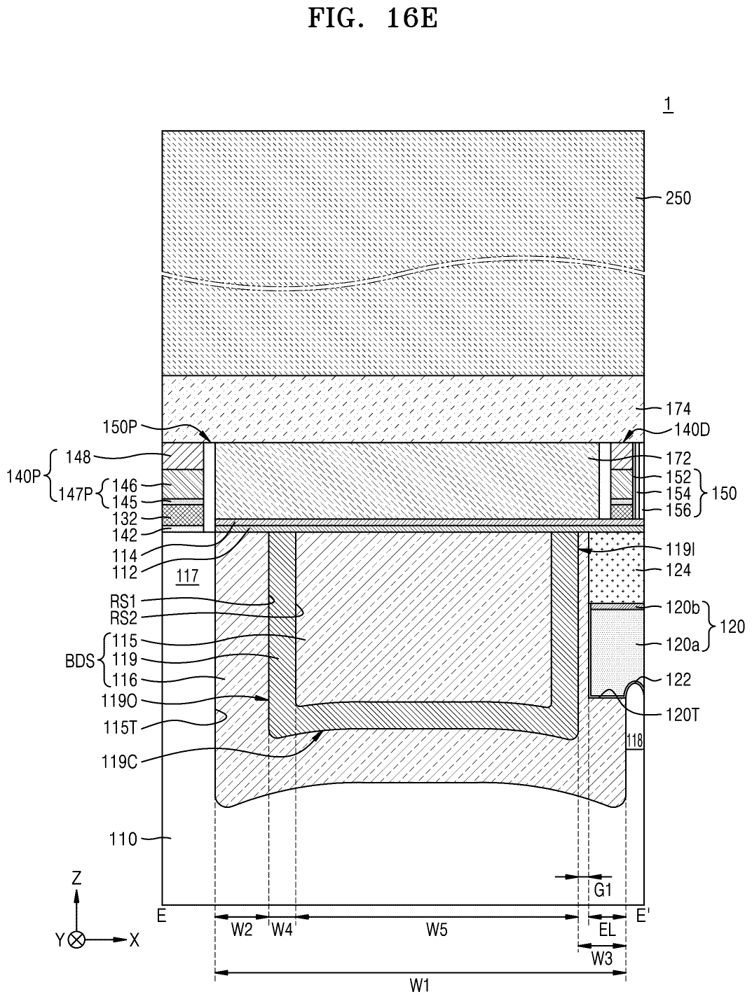

A region isolation structure 119 may be disposed in the boundary region BDR. The region isolation structure 119 may include an inner region isolation layer 119I and an outer region isolation layer 119O. The region isolation structure 119 may include a connection region isolation layer 119C (see FIG. 16E) connecting the inner region isolation layer 119I to the outer region isolation layer 119O. In a plan view, the inner region isolation layer 119I and the outer region isolation layer 119O may be spaced apart from each other. The connection region isolation layer 119C may connect a lower portion of the outer region isolation layer 119O to a lower portion of the inner region isolation layer 119I. The region isolation structure 119 may have a U-shaped vertical cross-section between the memory cell region CR and the peripheral region PR. For example, in a vertical cross-section cut along the memory cell region CR and the peripheral region PR facing each other with the boundary region BDR disposed therebetween, the region isolation structure 119 may have a U-shaped vertical cross-section. The outer region isolation layer 119O and the inner region isolation layer 119I may respectively correspond to vertical lines of the U-shaped vertical cross-section, and the connection region isolation layer 119C may correspond to a horizontal line connecting the vertical lines of the U-shaped vertical cross-section.

The inner region isolation layer 119I may be spaced apart from the memory cell region CR, and in a plan view, may be disposed adjacent to the memory cell region CR, extending along the edge of the memory cell region CR to surround the memory cell region CR. The inner region isolation layer 119I may completely surround the memory cell region CR. The outer region isolation layer 119O may be spaced apart from the sub-peripheral region SPR of the peripheral region PR, and in a plan view, may extend along the edge of the sub-peripheral region SPR. The outer region isolation layer 119O may be spaced apart from, and adjacent to, the inner region isolation layer 119I in a plan view. The outer region isolation layer 119O may extend along the periphery of the inner region isolation layer 119I to surround the memory cell region CR and the inner region isolation layer 119I. The outer region isolation layer 119O may completely surround the memory cell region CR and the inner region isolation layer 119I.

The inner region isolation layer 119I may have a generally rectangular shape in a plan view, and each side of the rectangular shape may extend wavily. The inner region isolation layer 119I may have substantially the same width in a plan view and extend along the edge of the memory cell region CR. Side surfaces of the inner region isolation layer 119I facing the memory cell region CR and the outer region isolation layer 119O may be include concave and convex surfaces. Side surfaces of the inner region isolation layer 119I facing the memory cell region CR and the outer region isolation layer 119O may be include alternating concave and convex surfaces. The outer region isolation layer 119O may have a generally rectangular shape in a plan view, and each side of the rectangular shape may extend linearly. Each of side surfaces of the outer region isolation layer 119O facing the inner region isolation layer 119I and the peripheral region PR may be a generally flat surface.

A device isolation layer 116 may be disposed between the inner region isolation layer 119I and the memory cell region CR and between the outer region isolation layer 119O and the sub-peripheral region SPR. The device isolation layer 116 may be formed below the connection region isolation layer 119C. A region isolation filling layer 115 may be disposed between the inner region isolation layer 119I and the outer region isolation layer 119O. For example, the region isolation filling layer 115 may fill the space defined by the inner region isolation layer 119I, the outer region isolation layer 119O, and the connection region isolation layer 119C.

A portion of the device isolation layer 116, the region isolation structure 119, and the region isolation filling layer 115 located in the boundary region BDR may be collectively referred to as a boundary structure BDS. The boundary structure BDS may surround the memory cell region CR. A portion of the device isolation layer 116 located in the boundary region BDR may be referred to as a boundary isolation layer.

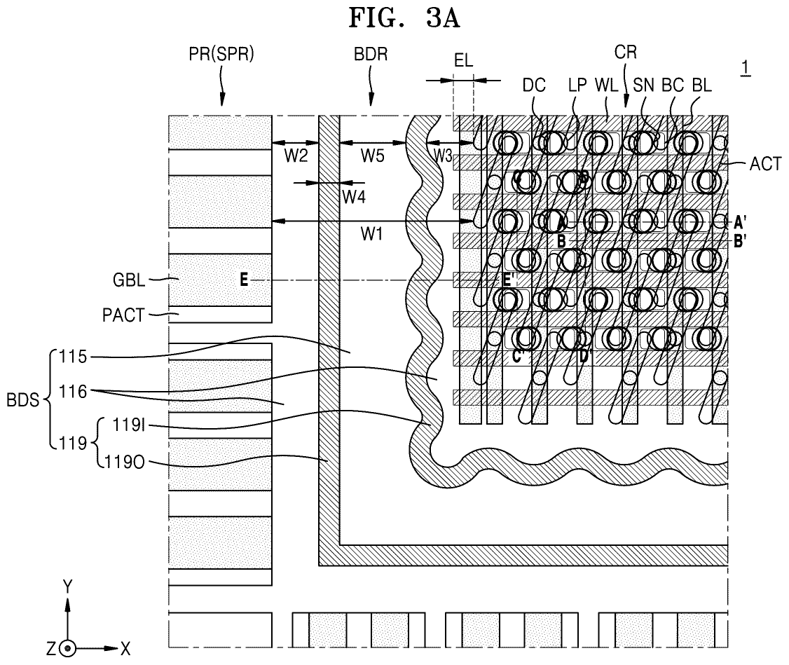

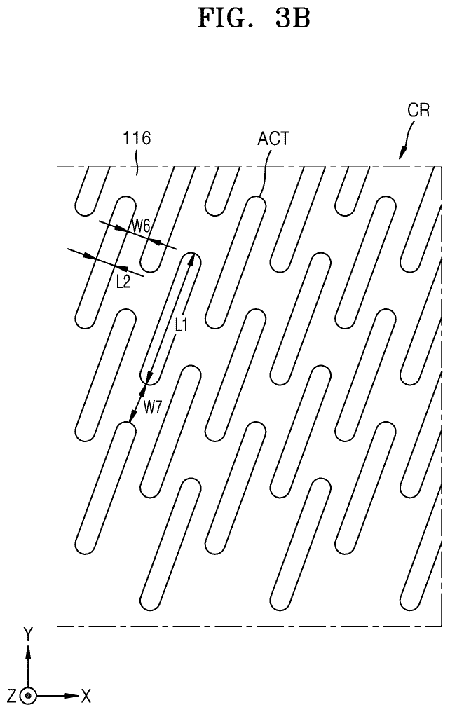

FIG. 3A and FIG. 3B are schematic plan layouts for explaining components of the semiconductor memory device 1 according to some embodiments.

Referring to FIG. 3A and FIG. 3B, the semiconductor memory device 1 may include the memory cell region CR, the peripheral region PR, and the boundary region BDR between the memory cell region CR and the peripheral region PR. The sub-peripheral region SPR of the peripheral region PR may be adjacent to the memory cell region CR with the boundary region BDR disposed therebetween.

The semiconductor memory device 1 may include a plurality of active regions ACT disposed in the memory cell region CR and a plurality of logic active regions PACT disposed in the peripheral region PR. The plurality of active regions ACT and the plurality of logic active regions PACT may be defined by the device isolation layer 116. The memory cell region CR may be the cell block SCB in which a plurality of memory cells shown in FIG. 1 are disposed, and the peripheral region PR may include the main peripheral region PRR and the sub-peripheral region SPR shown in FIG. 1. In some embodiments, the plurality of active regions ACT may be disposed in the memory cell region CR to each have a major axis in a diagonal direction with respect to a first horizontal direction (X direction) and a second horizontal direction (Y direction).

A plurality of word lines WL may extend parallel to each other in the first horizontal direction (X direction) across the plurality of active regions ACT in the memory cell region CR. The plurality of word lines WL may be spaced apart from each other in the second horizontal direction (Y direction). In some embodiments, in one active region ACT, a pair of word lines WL may extend in the first horizontal direction (X direction) parallel to each other across the one active region ACT. A plurality of bit lines BL may respectively extend parallel to each other in the second horizontal direction (Y direction) intersecting with the first horizontal direction (X direction). The plurality of bit lines BL may be disposed on the plurality of word lines WL and may be disposed crossing the plurality of word lines WL. The first horizontal direction (X direction) and the second horizontal direction (Y direction) may be substantially orthogonal to each other. The first horizontal direction (X direction) and the second horizontal direction (Y direction) may form a plane, which may be perpendicular to a vertical direction (Z direction).

In some embodiments, a bit line BL may extend in the second horizontal direction (Y direction) on one active region ACT. The plurality of bit lines BL may be respectively connected to the plurality of active regions ACT through a plurality of direct contacts DC. The plurality of direct contacts DC may be disposed at portions where the plurality of bit lines BL intersect with the plurality of active regions ACT.

In some embodiments, a plurality of buried contacts BC may be formed between adjacent bit lines BL among the plurality of bit lines BL. In some embodiments, the plurality of buried contacts BC may be disposed in a line in the first horizontal direction (X direction) and in a line in the second horizontal direction (Y direction). In some embodiments, a pair of buried contacts BC may be connected to an active region ACT. For example, a buried contact BC may be connected to each end portion of an active region ACT.

A plurality of landing pads LP may be respectively formed on the plurality of buried contacts BC. The plurality of landing pads LP may be disposed to at least partially overlap the plurality of buried contacts BC. In some embodiments, the plurality of landing pads LP may each extend to an upper portion of a bit line among adjacent bit lines BL.

A plurality of storage nodes SN may be formed on the plurality of landing pads LP. The plurality of storage nodes SN may be respectively formed on upper portions of the plurality of bit lines BL. The plurality of storage nodes SN may be respectively lower electrodes of a plurality of capacitors. The storage node SN may be connected to the active region ACT through the landing pad LP and the buried contact BC.

A plurality of gate line patterns GBL may be disposed in the peripheral region PR. The plurality of gate line patterns GBL may be disposed on the logic active region PACT in the peripheral region PR. In FIG. 3A, a plurality of gate line patterns GBL have a generally constant width in the second horizontal direction (Y direction) and extend parallel to each other in the first horizontal direction (X direction) on the logic active region PACT, or have a generally constant width in the first horizontal direction (X direction) and extend parallel to each other in the second horizontal direction (Y direction) on the logic active region PACT, but are not limited thereto. For example, each of the plurality of gate line patterns GBL may have various widths or a variable width, may be curved, or may extend in various directions.

In FIG. 3A, components other than the plurality of logic active regions PACT and the plurality of gate line patterns GBL may be omitted in the peripheral region PR for convenience of illustration. In addition, in FIG. 3A, the plurality of gate line patterns GBL are respectively disposed on the plurality of logic active regions PACT but are not limited thereto. For example, at least some of the plurality of gate line patterns GBL may extend outside the logic active region PACT, that is, onto the device isolation layer 116.

The plurality of gate line patterns GBL may be respectively formed at the same level as the plurality of bit lines BL. In some embodiments, the plurality of gate line patterns GBL and the plurality of bit lines BL may include the same material, or may include the same material in part. For example, a process of forming all or some of the plurality of gate line patterns GBL may be the same as a process of forming all or some of the plurality of bit lines BL.

The boundary region BDR may extend between the memory cell region CR and the peripheral region PR. The region isolation structure 119 may be disposed in the boundary region BDR. The region isolation structure 119 may include the inner region isolation layer 119I, the outer region isolation layer 119O, and the connection region isolation layer 119C (see FIG. 16E) connecting the inner region isolation layer 119I to the outer region isolation layer 119O. In a plan view, the inner region isolation layer 119I and the outer region isolation layer 119O may be spaced apart from each other. The inner region isolation layer 119I may be spaced apart from the memory cell region CR with the device isolation layer 116 disposed therebetween, and may be adjacent to the memory cell region CR in a plan view. The outer region isolation layer 119O may be spaced apart from the sub-peripheral region SPR with the device isolation layer 116 disposed therebetween, and may be adjacent to the sub-peripheral region SPR in a plan view.

The inner region isolation layer 119I may have substantially the same width in a plan view and may extend wavily along an edge of the memory cell region CR. Side surfaces of the inner region isolation layer 119I facing the memory cell region CR and the outer region isolation layer 119O may include a concave and convex surface. Side surfaces of the inner region isolation layer 119I facing the memory cell region CR and the outer region isolation layer 119O may be include alternating concave and convex surfaces. A portion of the device isolation layer 116 that is in contact with the inner region isolation layer 119I may have a concave and convex surface corresponding to the side surface of the inner region isolation layer 119I.

The outer region isolation layer 119O may have substantially the same width in a plan view and may extend along an edge of the sub-peripheral region SPR. The region isolation filling layer 115 may be disposed between the inner region isolation layer 119I and the outer region isolation layer 119O.

The plurality of active regions ACT and the plurality of logic active regions PACT may be spaced apart from each other by a first width W1. For example, a portion of the device isolation layer 116 located between the active region ACT located at the outermost part of the memory cell region CR and the logic active region PACT located at the outermost part of the peripheral region PR, which are adjacent to each other in a plan view, a portion of the region isolation structure 119, and a portion of the region isolation filling layer 115 may together have the first width W1. In some embodiments, the first width W1 may be hundreds of nanometers (nm) or more. For example, the first width W1 may be about 400 nm to about 700 nm. The plurality of active regions ACT may be disposed in the memory cell region CR to each have a major axis in the diagonal direction with respect to the first horizontal direction (X direction) and the second horizontal direction (Y direction), and a value of the first width W1 may have a deviation. In some embodiments, the first width W1 may have a deviation of tens of Angstroms (Å) or less according to an arrangement of the plurality of active regions ACT.

The logic active region PACT and the outer region isolation layer 119O of the region isolation structure 119 may be spaced apart from each other by a second width W2. For example, a portion of the device isolation layer 116 located between the logic active region PACT located at the outermost part of the peripheral region PR and the outer region isolation layer 119O of the region isolation structure 119 may have the second width W2. The active region ACT and the inner region isolation layer 119I of the region isolation structure 119 may be spaced apart from each other by a third width W3. For example, a portion of the device isolation layer 116 located between the active region ACT located at the outermost part of the memory cell region CR and the inner region isolation layer 119I of the region isolation structure 119 may have the third width W3. In some embodiments, each of the second width W2 and the third width W3 may be about several hundred Å. The second width W2 and the third width W3 may have substantially the same width. For example, a minimum value of the second width W2 may be the same as the minimum value of the third width W3. The third width W3 may have a deviation of tens of Å or less. The third width W3 may have a deviation according to the arrangement of the plurality of active regions ACT and/or the shape of the inner region isolation layer 119I.

In some embodiments, the shape of the inner region isolation layer 119I and the shape of the adjacent active region ACT may correspond to each other. For example, a concave portion of the inner region isolation layer 119I facing the memory cell region CR may correspond to a proximate end portion of an adjacent active region ACT, and a convex portion of the inner region isolation layer 119I facing the memory cell region CR may correspond to a middle portion of an adjacent active region ACT, where the proximate end portion of the active region ACT may be closer to the peripheral region PR than the middle portion of the active region ACT.

The region isolation structure 119 may have a fourth width W4. For example, each of the inner region isolation layer 119I and the outer region isolation layer 119O of the region isolation structure 119 may have substantially the same width, which may be the fourth width W4. The fourth width W4 may be about 100 Å to about 200 Å. In some embodiments, the second width W2 and the third width W3 may be about three times or more larger than the fourth width W4.

The region isolation filling layer 115 may have a fifth width W5. For example, the region isolation filling layer 115 between the inner region isolation layer 119I and the outer region isolation layer 119O may have the fifth width W5. For example, the fifth width W5 may be less than the first width W1 and may be about 300 nm to about 500 nm. In some embodiments, a value of the fifth width W5 may have a deviation according to a side surface of the inner region isolation layer 119I facing the outer region isolation layer 119O having the concave and convex surface. In some embodiments, the fifth width W5 may have a deviation of tens of Å or less. The fourth width W4 may be less than each of the second width W2 and the third width W3. Each of the second width W2 and the third width W3 may be less than the fifth width W5. The fifth width W5 may be less than the first width W1.

Each of the plurality of active regions ACT may have a first length L1 in a major axis direction and a second length L2 in a minor axis direction. Among the plurality of active regions ACT, active regions ACT adjacent to each other in the minor axis direction of the active region ACT may be spaced apart from each other by a sixth width W6, and active regions ACT adjacent to each other in the major axis direction of the active region ACT may be spaced apart from each other by a seventh width W7. For example, a portion of the device isolation layer 116 located between adjacent active regions ACT in the minor axis direction of the active region ACT among the plurality of active regions ACT may have the sixth width W6, and a portion of the device isolation layer 116 located between adjacent active regions ACT in the major axis direction of the active region ACT may have the seventh width W7. The first length L1, the second length L2, the sixth width W6, and the seventh width W7 may each be several Å to tens of Å. The first length L1 may have a value greater than about five times or more the second length L2. The sixth width W6 may have a value greater than the second length L2 and less than the seventh width W7. The fourth width W4 may have a value greater than each of the first length L1, the second length L2, the sixth width W6, and the seventh width W7.

The plurality of word lines WL may extend in the first horizontal direction (X direction) by an extension length EL from an edge of the active region ACT. The edge of the active region ACT may be located at the outermost part of the memory cell region CR in the first horizontal direction (X direction). The plurality of word lines WL may extend in the first horizontal direction (X direction) by an extension length EL from a proximate end portion of an adjacent active region ACT located at the outermost part of the memory cell region CR in the first horizontal direction (X direction). The extension length EL may have a value less than the third width W3. Therefore, the plurality of word lines WL and the region isolation structure 119 may not overlap each other in a vertical direction (Z direction), and the plurality of word lines WL and the region isolation structure 119 may be spaced apart from each other in a plan view.

Each of the first width W1, the second width W2, the third width W3, the fourth width W4, the fifth width W5, and the sixth width W6, and the seventh width W7 may be a width in a horizontal direction, for example, the first horizontal direction (X direction), the second horizontal direction (Y direction), or a diagonal direction with respect to the first horizontal direction (X direction) and the second horizontal direction (Y direction). Unless specifically stated herein, a ‘width’ refers to a width in the horizontal direction.

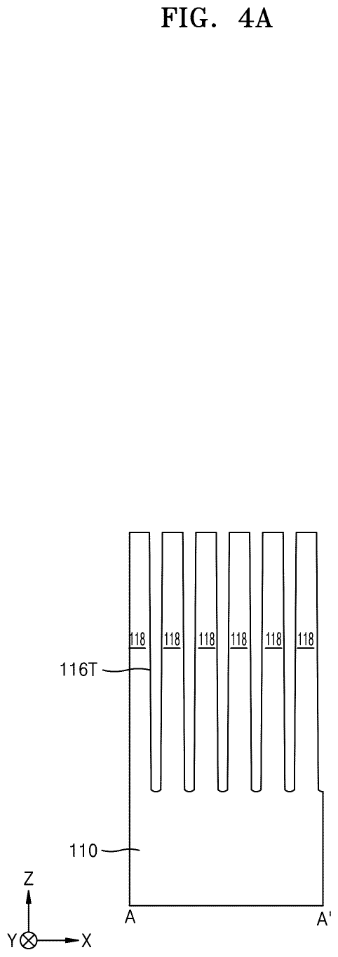

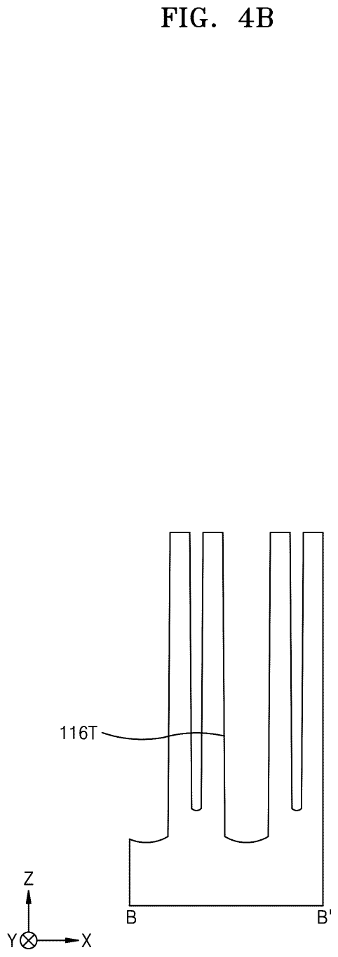

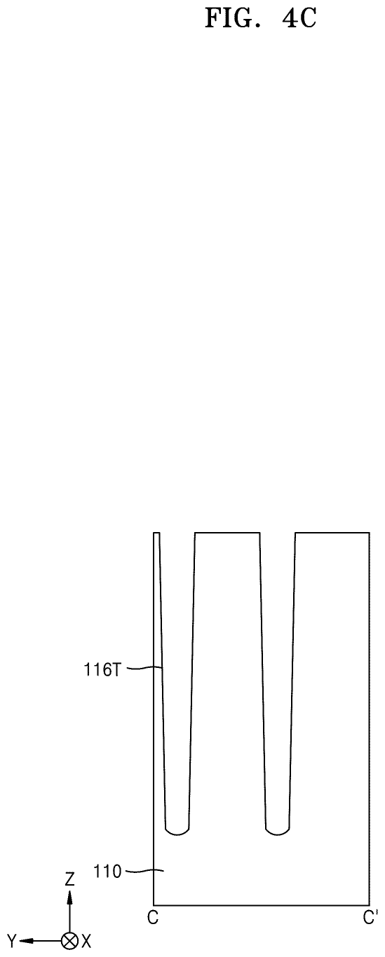

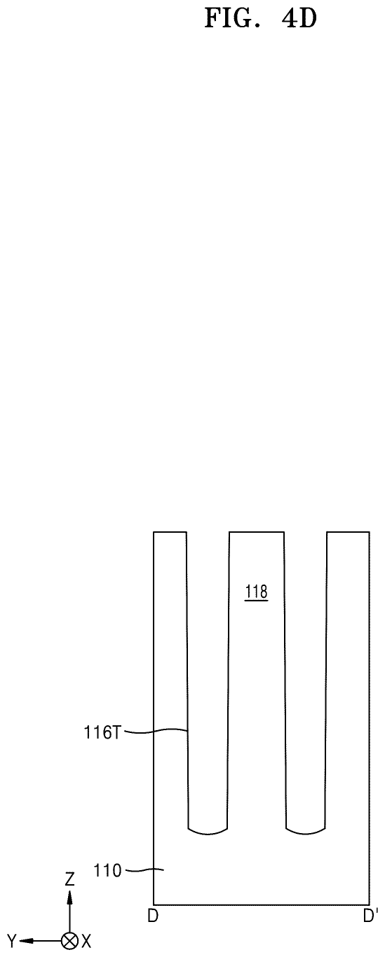

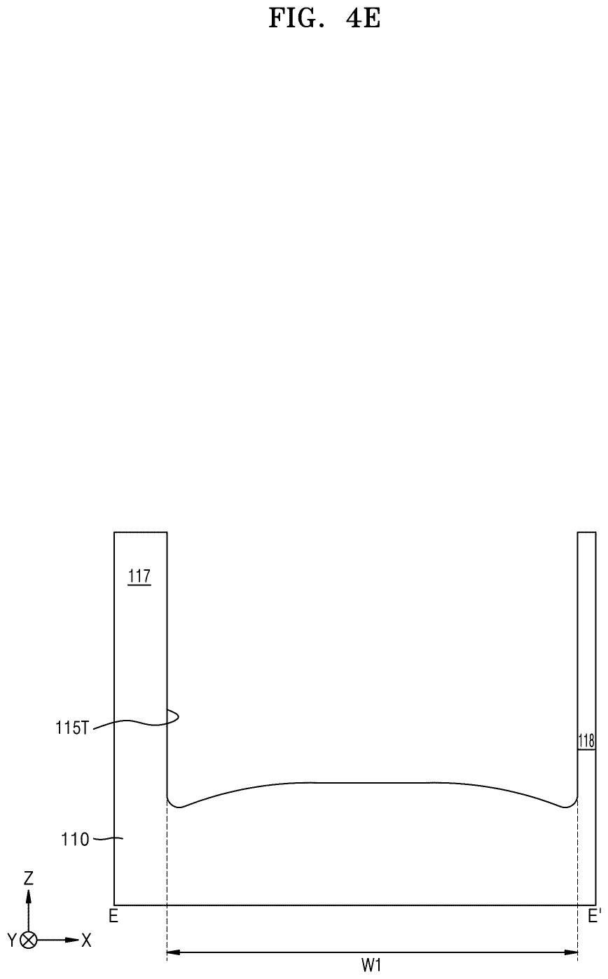

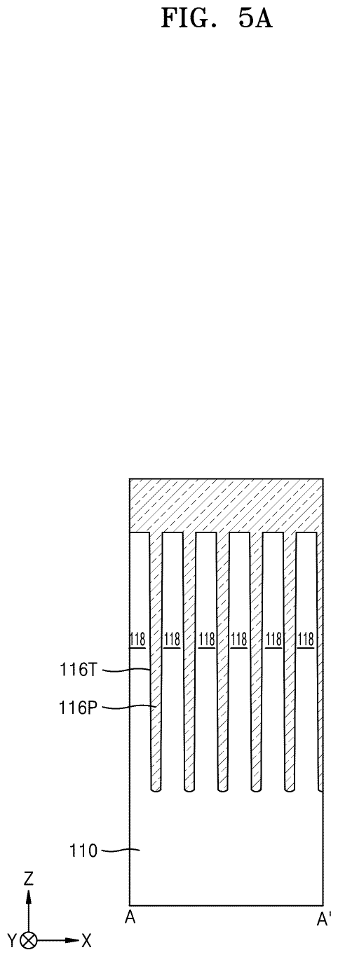

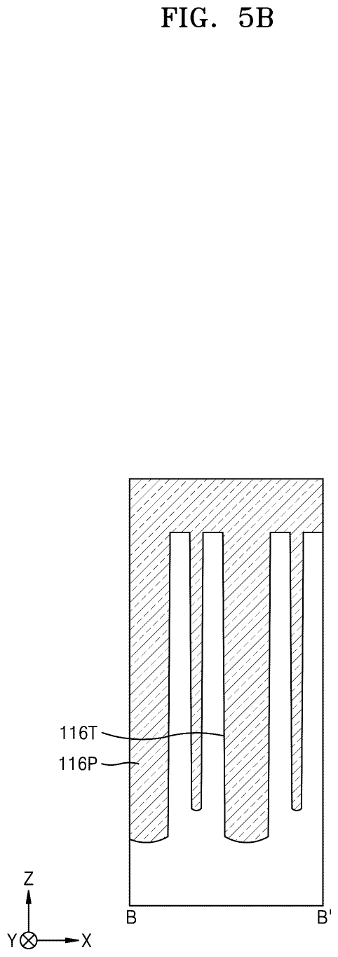

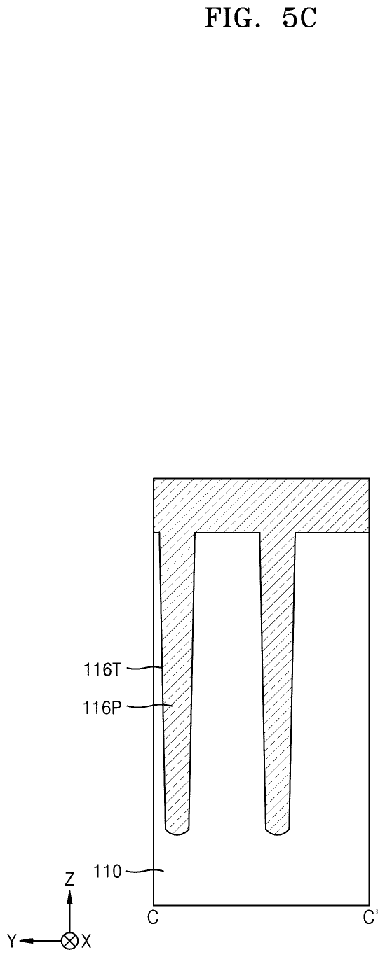

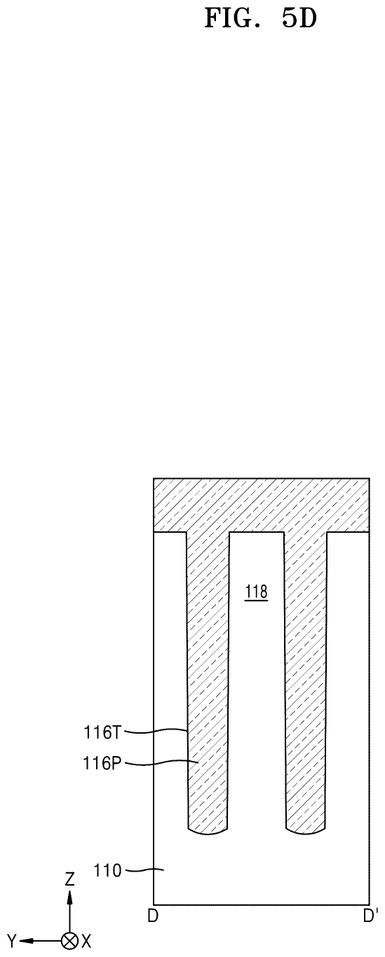

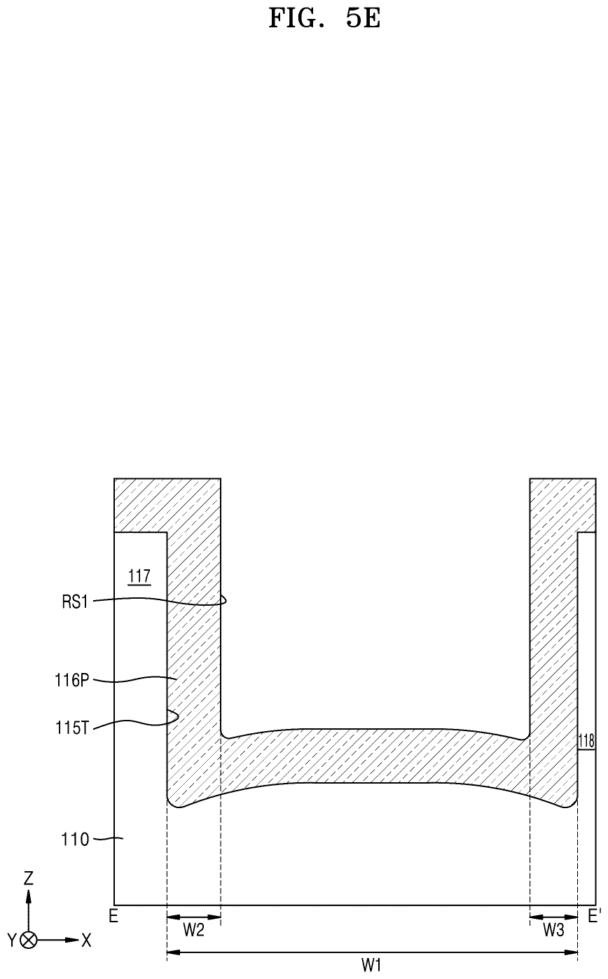

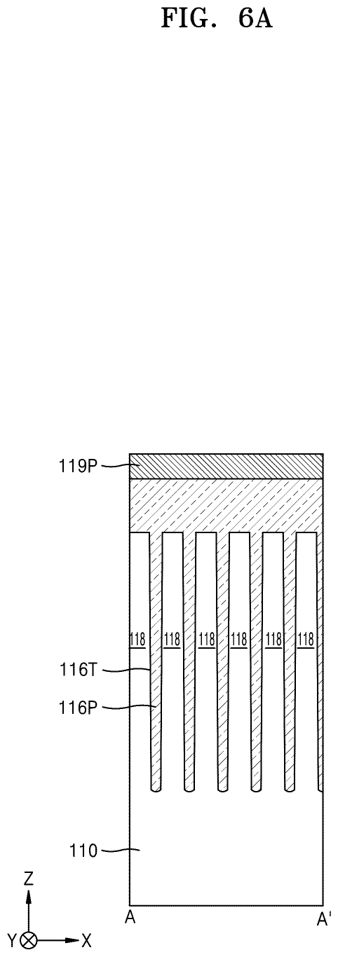

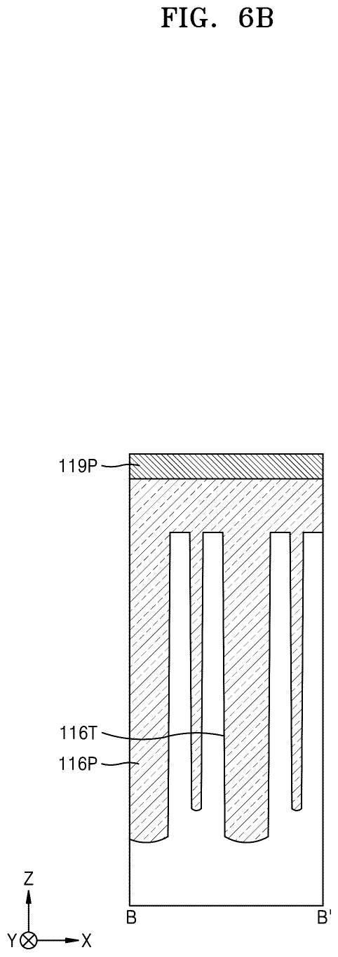

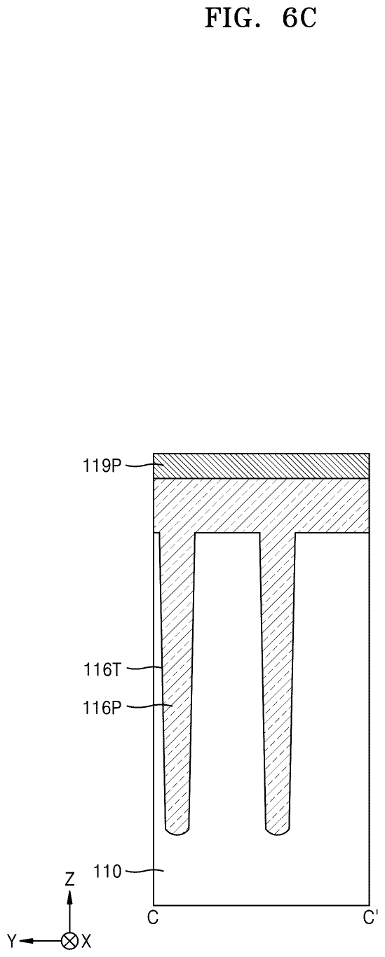

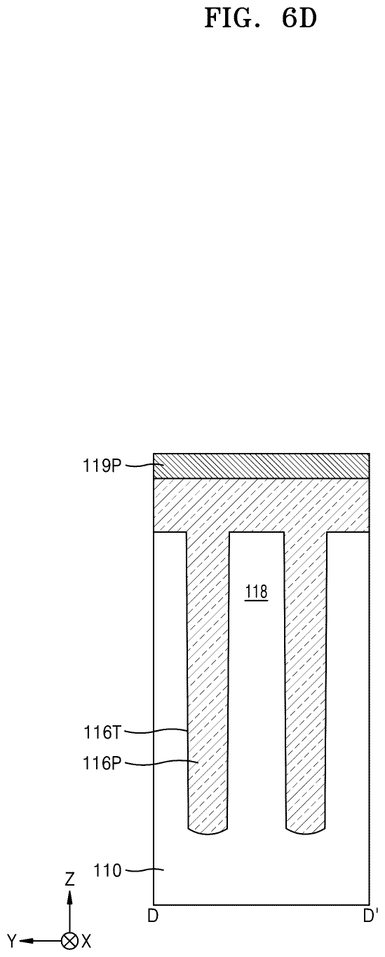

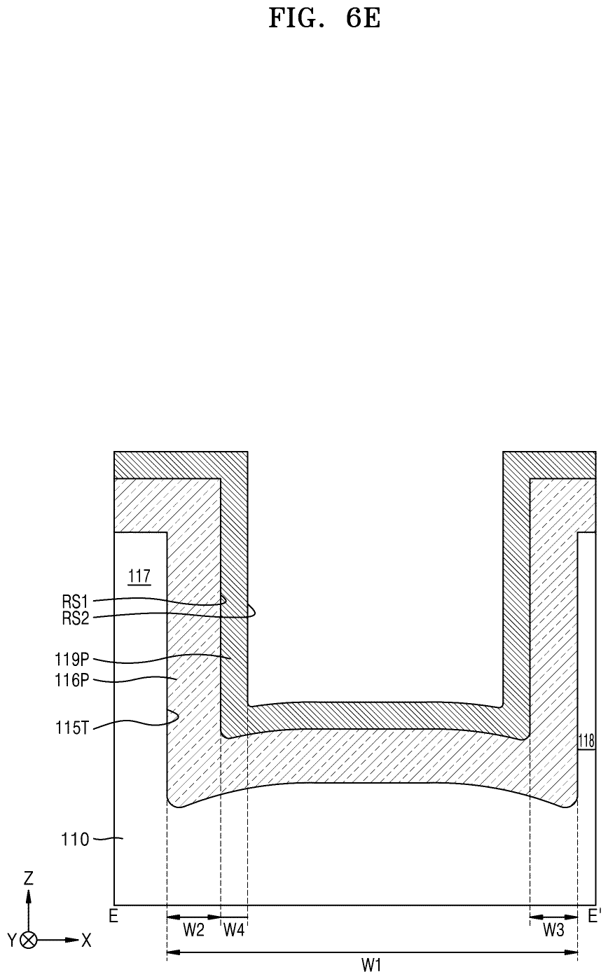

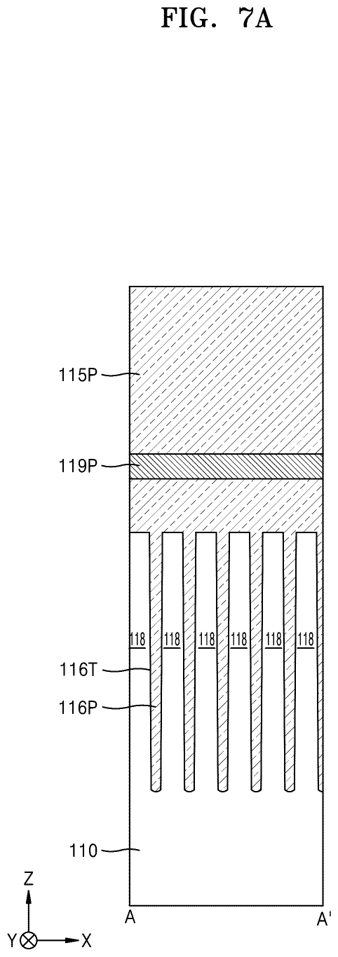

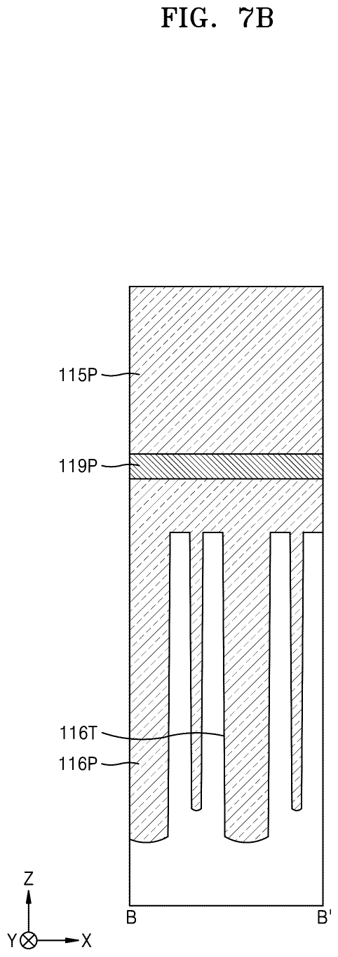

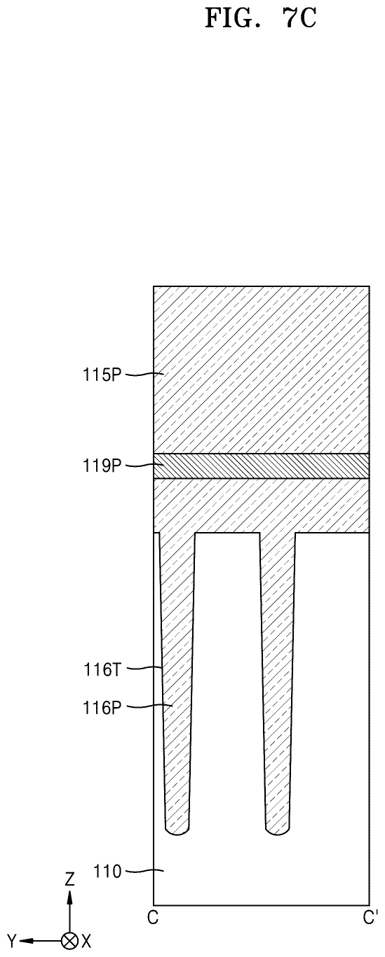

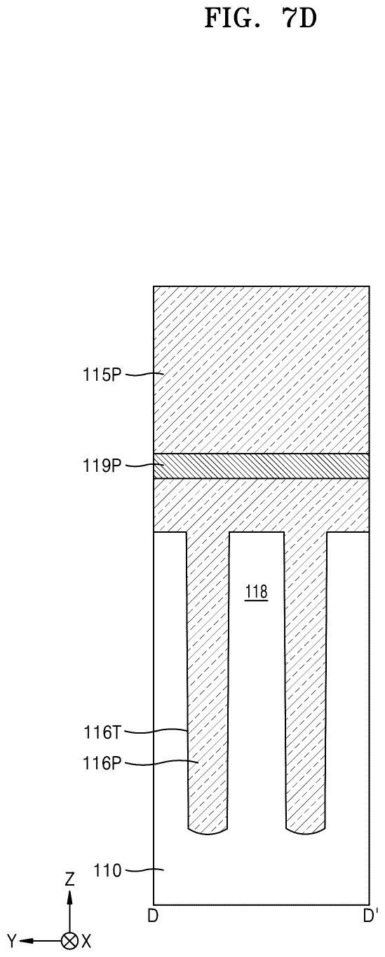

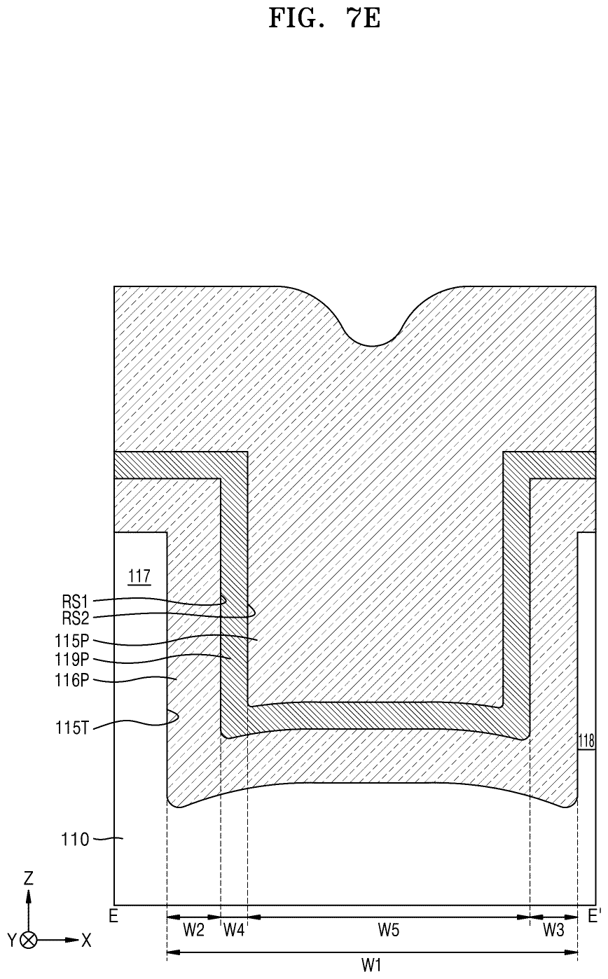

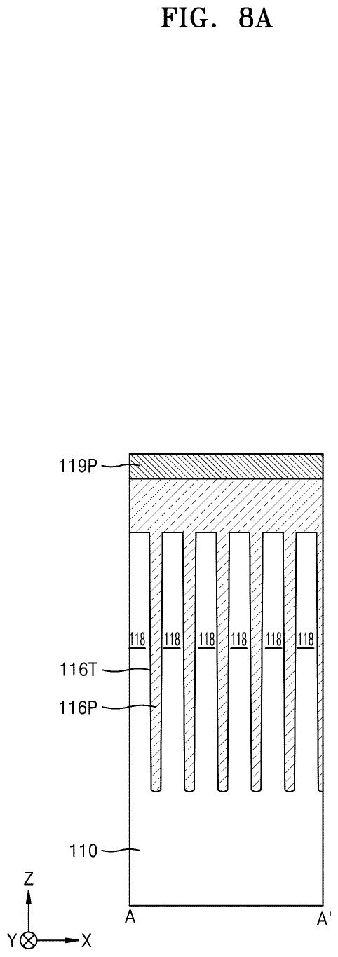

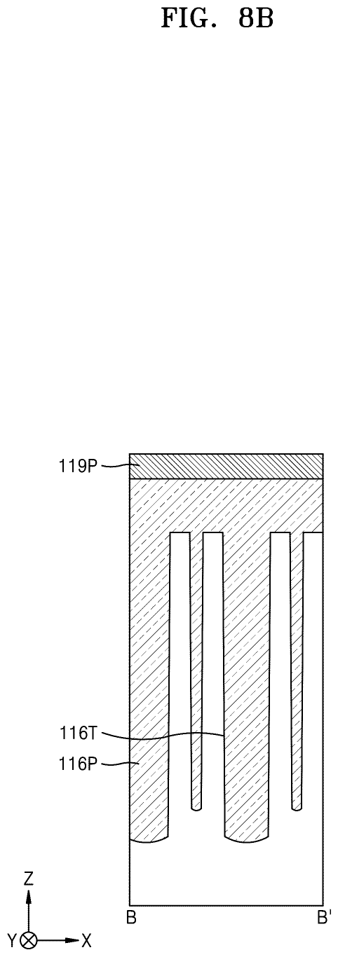

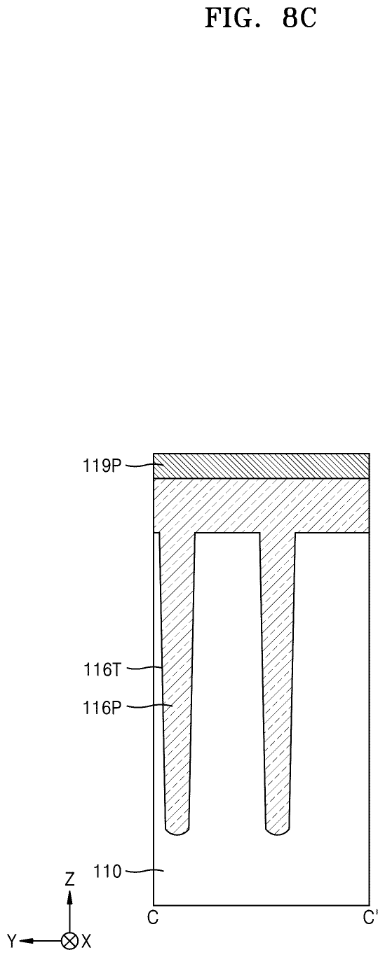

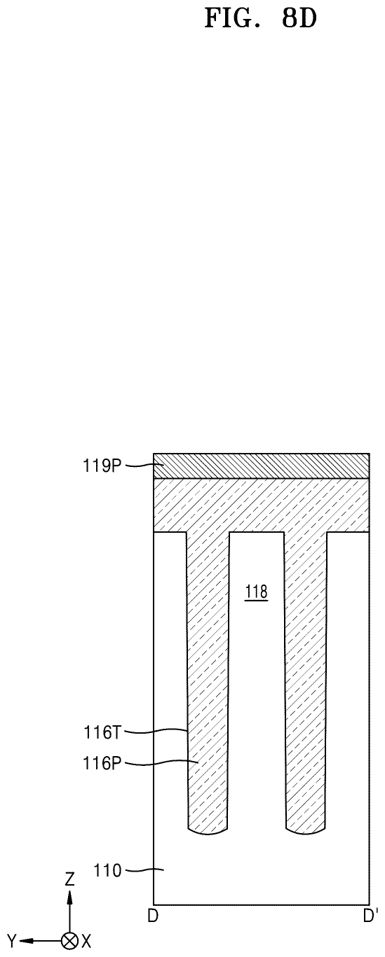

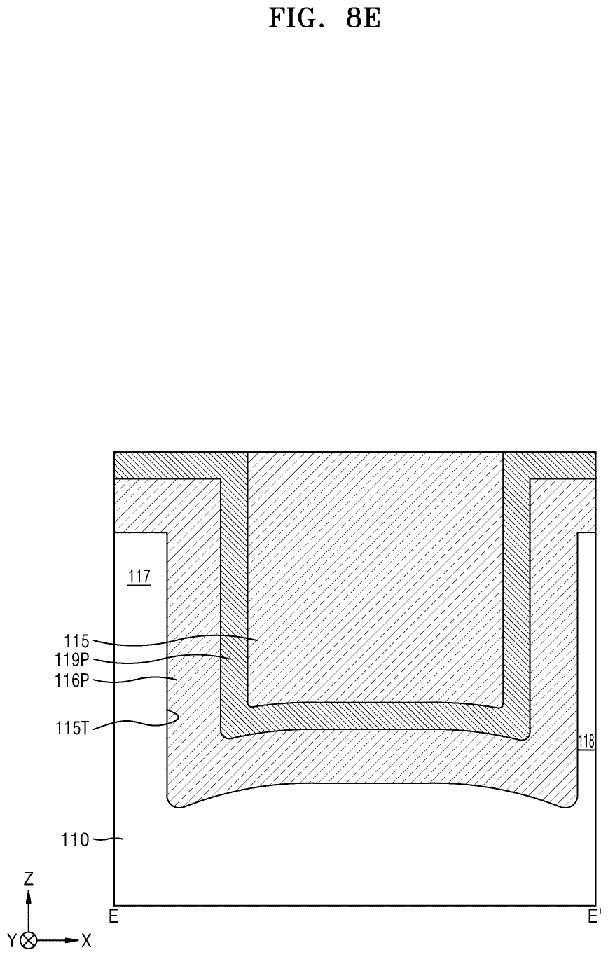

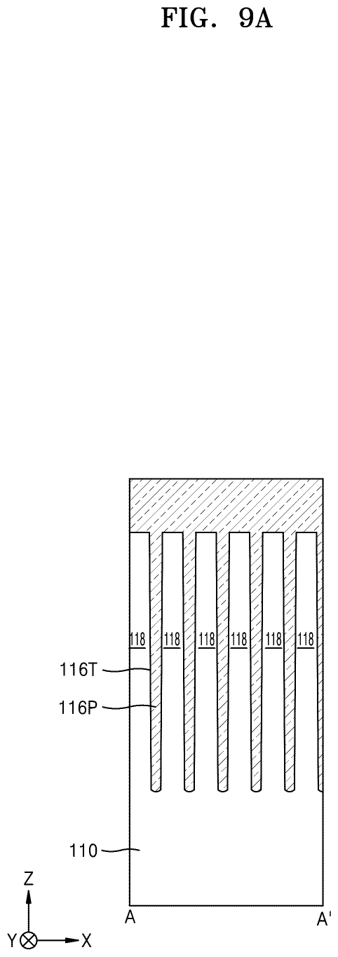

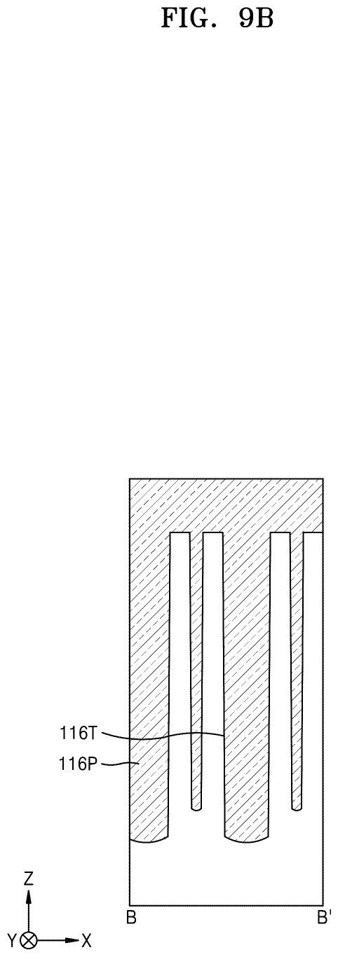

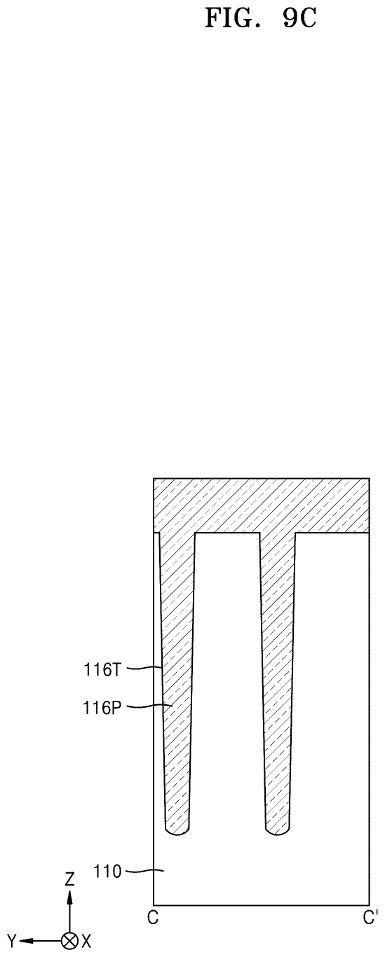

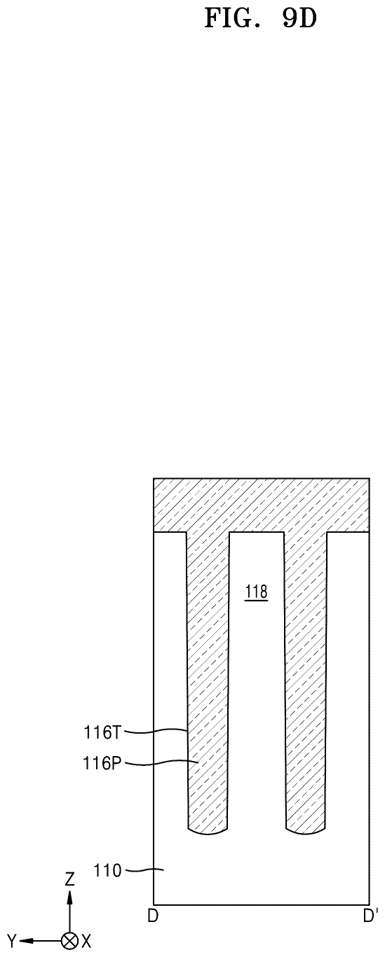

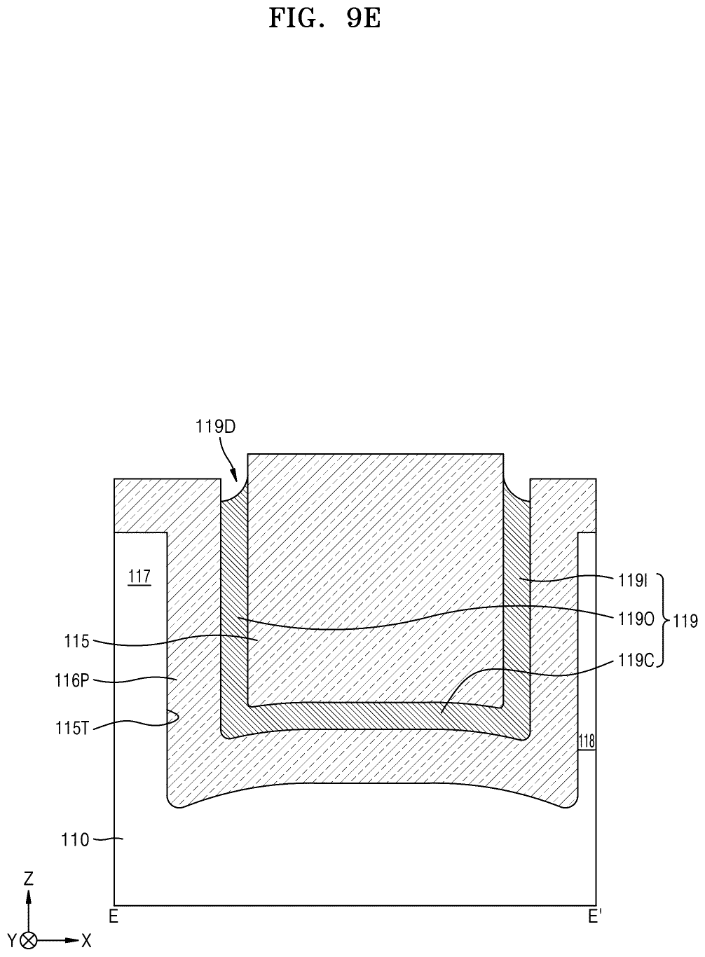

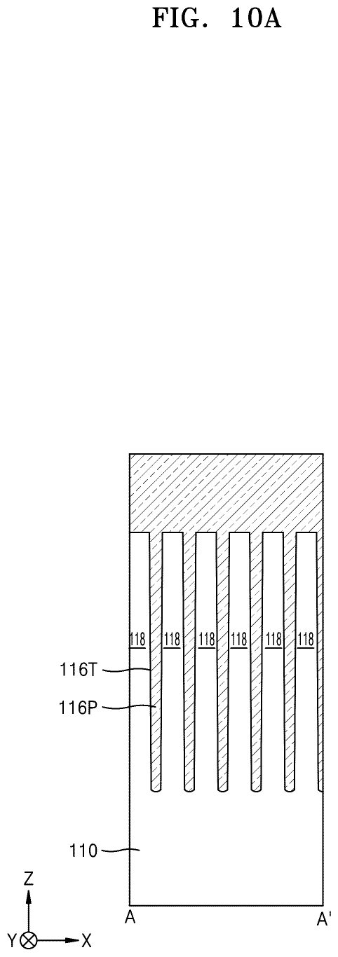

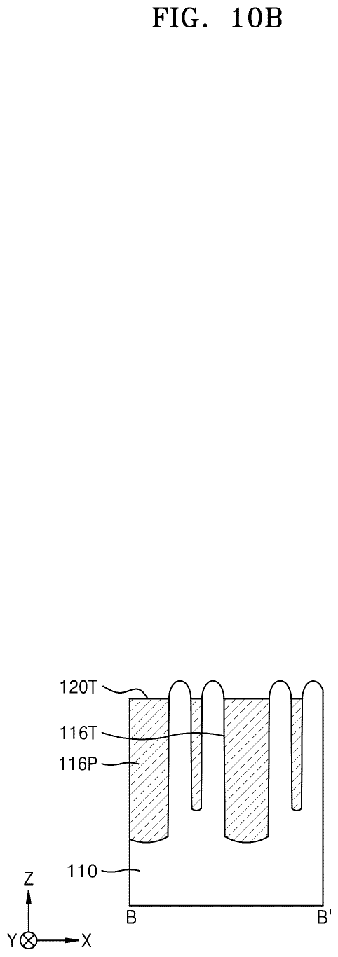

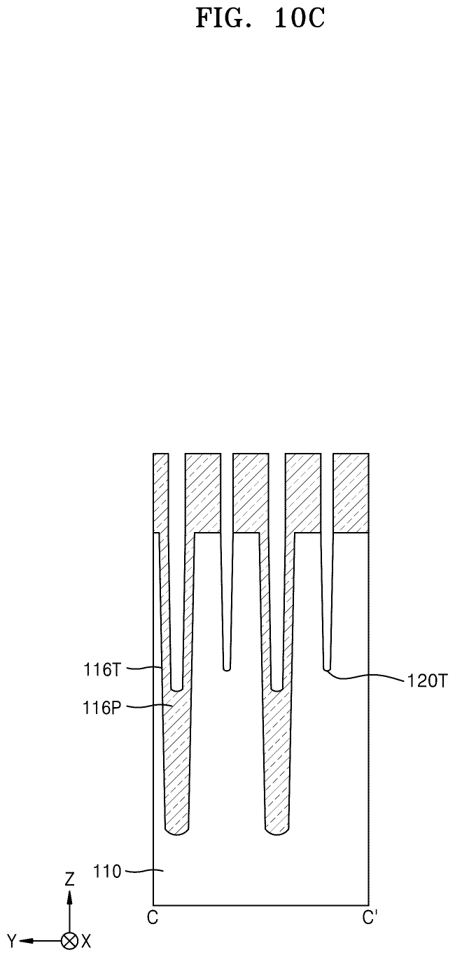

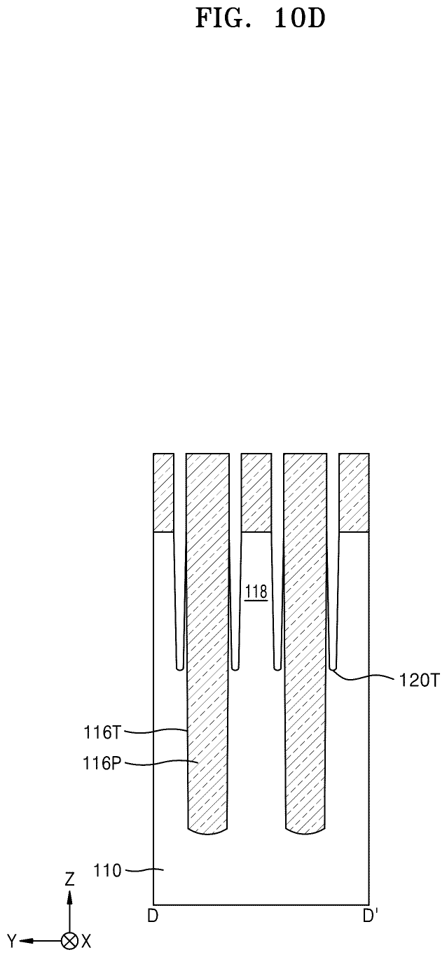

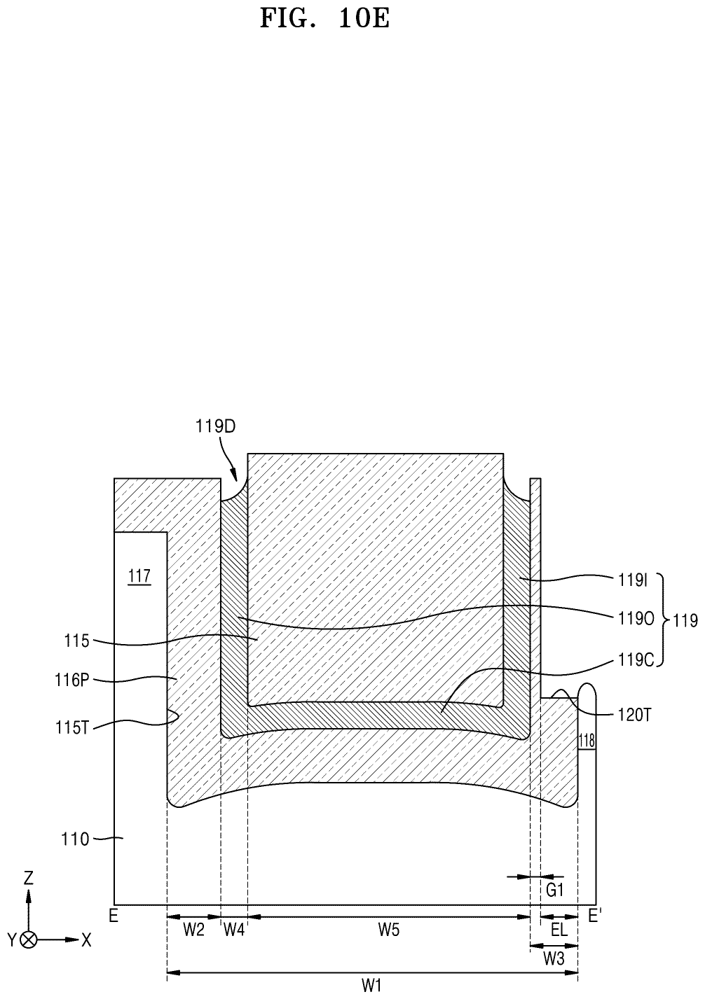

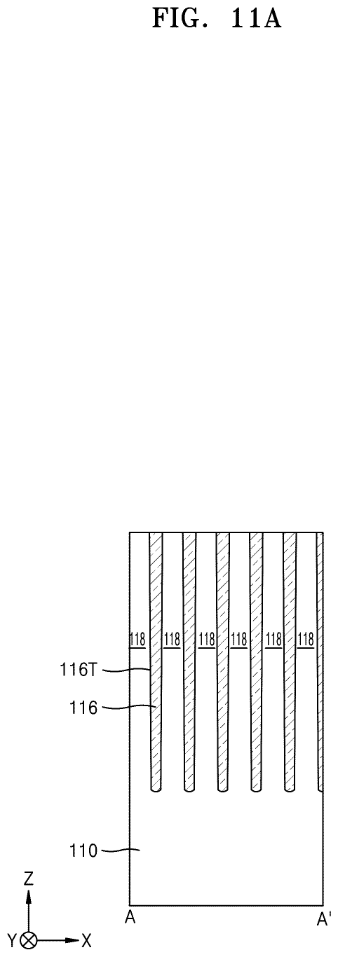

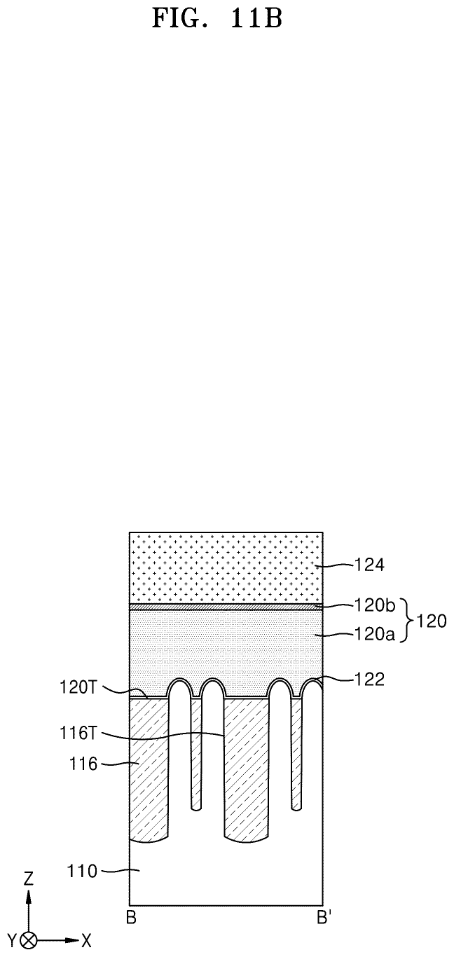

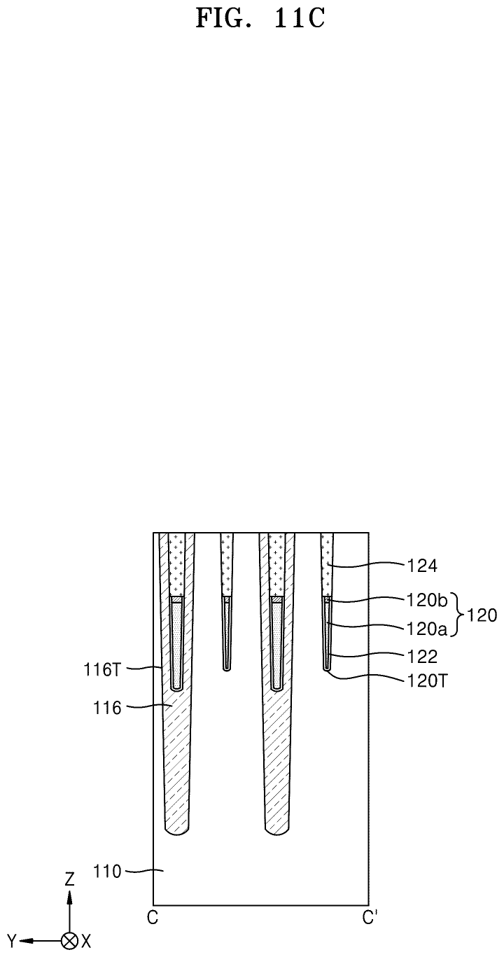

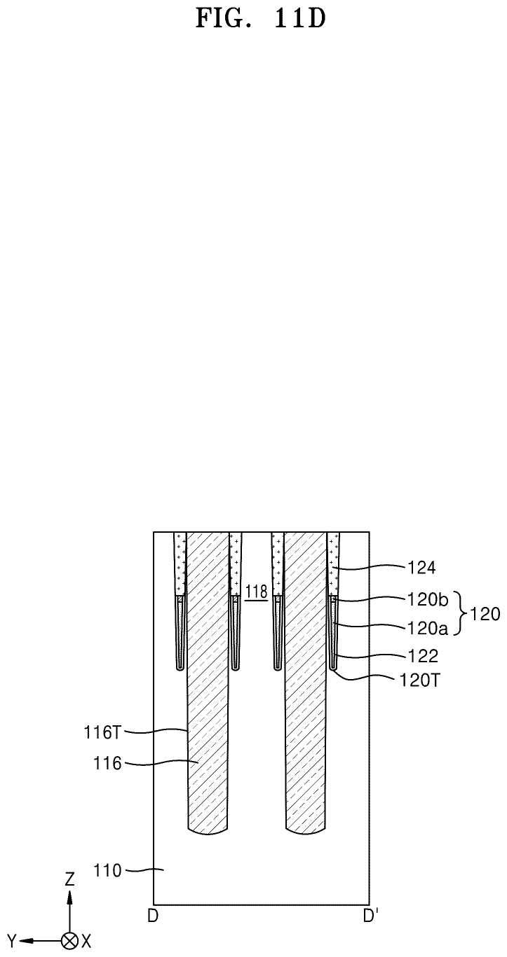

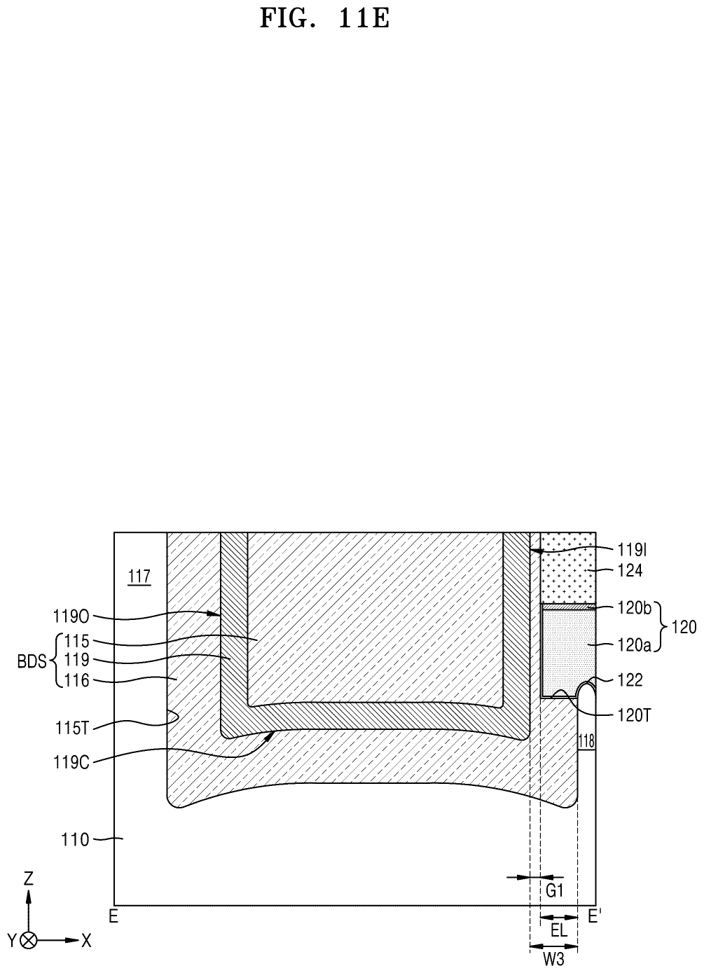

FIG. 4A to FIG. 4E, FIG. 5A to FIG. 5E, FIG. 6A to FIG. 6E, FIG. 7A to FIG. 7E, FIG. 8A to FIG. 8E, FIG. 9A to FIG. 9E, FIG. 10A to FIG. 10E, FIG. 11A to FIG. 11E, FIG. 12A to FIG. 12E, FIG. 13A to FIG. 13E, FIG. 14A to 14D, and FIG. 15A to FIG. 15D are cross-sectional views illustrating a method of manufacturing the semiconductor memory device 1, according to some embodiments. FIG. 16A to FIG. 16E are cross-sectional views illustrating the semiconductor memory device 1, according to some embodiments. Specifically, FIG. 4A, FIG. 5A, FIG. 6A, FIG. 7A, FIG. 8A, FIG. 9A, FIG. 10A, FIG. 11A, FIG. 12A, FIG. 13A, FIG. 14A, FIG. 15A, and FIG. 16A are cross-sectional views taken along the line A-A′ of FIG. 3A. FIG. 4B, FIG. 5B, FIG. 6B, FIG. 7B, FIG. 8B, FIG. 9B, FIG. 10B, FIG. 11B, FIG. 12B, FIG. 13B, FIG. 14B, FIG. 15B, and FIG. 16B are cross-sectional views taken along the line B-B′ of FIG. 3A. FIG. 4C, FIG. 5C, FIG. 6C, FIG. 7C, FIG. 8C, FIG. 9C, FIG. 10C, FIG. 11C, FIG. 12C, FIG. 13C, FIG. 14C, FIG. 15C, and FIG. 16C are cross-sectional views taken along the line C-C′ of FIG. 3A. FIG. 4D, FIG. 5D, FIG. 6D, FIG. 7D, FIG. 8D, FIG. 9D, FIG. 10D, FIG. 11D, FIG. 12D, FIG. 13D, FIG. 14D, FIG. 15D, and FIG. 16D are cross-sectional views taken along the line D-D′ of FIG. 3A. FIG. 4E, FIG. 5E, FIG. 6E, FIG. 7E, FIG. 8E, FIG. 9E, FIG. 10E, FIG. 11E, FIG. 12E, FIG. 13E, and FIG. 16E are cross-sectional views taken along the line E-E′ of FIG. 3A.

Referring to FIG. 4A to FIG. 4E, a device isolation trench 116T and a region isolation trench 115T may be formed in the substrate 110. The device isolation trench 116T and the region isolation trench 115T may be formed by removing a part of the substrate 110. The device isolation trench 116T may be formed in the memory cell region CR and the peripheral region PR shown in FIG. 3A, and the region isolation trench 115T may be formed in the boundary region BDR shown in FIG. 3A.

The substrate 110 may include, for example, silicon (Si), crystalline Si, polycrystalline Si, or amorphous Si. In some embodiments, the substrate 110 may include a semiconductor element such as germanium (Ge), or at least one compound semiconductor selected from silicon germanium (SiGe), silicon carbide (SiC), gallium arsenide (GaAs), indium arsenide (InAs), or indium phosphide (InP). In some embodiments, the substrate 110 may have a silicon on insulator (SOI) structure. For example, the substrate 110 may include a buried oxide (BOX) layer. The substrate 110 may include a conductive region, for example, a well doped with an impurity, or a structure doped with an impurity.

A plurality of active regions 118 may be defined in the substrate 110 in the memory cell region CR by the device isolation trench 116T. A plurality of logic active regions 117 may be defined in the substrate 110 in the peripheral region PR by the device isolation trench 116T. In some embodiments, the plurality of active regions 118 and/or the plurality of logic active regions 117 defined by the device isolation trench 116T may be formed through an extreme ultraviolet (EUV) lithography process. The active region 118 may have a minor axis and a major axis and may have a relatively long island shape extending in a major axis direction in a plan view, substantially similar to the active region ACT illustrated in FIG. 3A and FIG. 3B. The plurality of active regions 118 may be disposed as columns arranged in a diagonal direction with respect to the first horizontal direction (X direction) and the second horizontal direction (Y direction), and may be disposed in a column in the second horizontal direction (Y direction). For example, the plurality of active regions 118 disposed at edge portions of the memory cell region CR may be disposed as columns arranged in the second horizontal direction (Y direction). Each of the logic active regions 117 may have a rectangular shape in a plan view, similar to the logic active region PACT illustrated in FIG. 3A, but this is an example, and the present specification is not limited thereto, and the logic active regions 117 may have various planar shapes. The plurality of active regions 118 and the plurality of logic active regions 117 may be spaced apart from each other with the region isolation trench 115T therebetween. The region isolation trench 115T may be formed to have the first width W1. In some embodiments, the first width W1 may be hundreds of nm or more. For example, the first width W1 may be about 400 nm to about 700 nm.

Referring to FIG. 5A to FIG. 5E, a device isolation material layer 116P may be disposed in the device isolation trench 116T and a part of the region isolation trench 115T. The device isolation material layer 116P may be formed to fill the device isolation trench 116T and a part of the region isolation trench 115T For example, the device isolation material layer 116P may include a material including at least one of silicon oxide, silicon nitride, or silicon oxynitride. The device isolation material layer 116P may include a single layer including one type of insulating layer, a double layer including two types of insulating layers, or a multi-layer including a combination of at least two or more types of insulating layers. For example, the device isolation material layer 116P may include a single layer formed of an oxide layer. In some embodiments, the device isolation material layer 116P may include silicon oxide. For example, the device isolation material layer 116P may include a double layer or multilayer including an oxide layer and a nitride layer, and a ratio of the material of the device isolation material layer 116P may be greater in oxide than in nitride. For example, a majority of the material of the device isolation material layer 116P may be oxide. In some embodiments, an upper surface of the device isolation material layer 116P may include only oxide.

The device isolation material layer 116P may be disposed in the device isolation trench 116T. The device isolation material layer 116P may cover upper surfaces of the plurality of active regions 118 and upper surfaces of the plurality of logic active regions 117. The device isolation material layer 116P may be formed to completely fill the device isolation trench 116T and cover upper surfaces of the plurality of active regions 118 and upper surfaces of the plurality of logic active regions 117. The device isolation material layer 116P may be formed to fill only a part of the region isolation trench 115T. The device isolation material layer 116P may cover a side surface of the logic active region 117 located at the outermost part of the peripheral region PR with a thickness corresponding to the second width W2, may cover a side surface of the active region ACT located at the outermost part of the memory cell region CR with a thickness corresponding to the third width W3, and may cover an upper surface of the substrate 110 exposed at a bottom surface of the region isolation trench 115T with a thickness that is generally similar to the second width W2 and the third width W3. In some embodiments, each of the second width W2 and the third width W3 may be about hundreds of Å. That is, the device isolation material layer 116P may have a thickness of about hundreds of Å and may cover inner and bottom surfaces of the region isolation trench 115T. A first recess space RS1 may be limited by the device isolation material layer 116P in the region isolation trench 115T.

A side surface of a portion of the device isolation material layer 116P covering the active region 118 in the inner surface of the region isolation trench 115T and facing the first recess space RS1 may be formed to have a concave and convex surface. For example, the side surface of a portion of the device isolation material layer 116P covering the active region 118 in the inner surface of the region isolation trench 115T and facing the first recess space RS1 may be formed to have a surface with alternating concave and convex portions.

Referring to FIG. 6A to FIG. 6E, a region isolation material layer 119P may be disposed on the device isolation material layer 116P. The region isolation material layer 119P may be formed to cover the device isolation material layer 116P. The region isolation material layer 119P may include nitride. For example, the region isolation material layer 119P may include silicon nitride. The region isolation material layer 119P may be disposed in the region isolation trench 115T and the first recess space RS1. The region isolation material layer 119P may be formed to fill the region isolation trench 115T and a part of the first recess space RS1. The region isolation material layer 119P may have a thickness corresponding to the fourth width W4 and may cover the device isolation material layer 116P. In some embodiments, the fourth width W4 may be about 100 Å to about 200 Å. For example, the region isolation material layer 119P may have a thickness of about 100 Å to about 200 Å and may cover inner surfaces and bottom surfaces of the first recess space RS1. A second recess space RS2 may be limited by the region isolation material layer 119P in the first recess space RS1.

Each of the side surfaces of a portion of the region isolation material layer 119P covering the inner surface of the first recess space RS1 and facing the active region 118 may be formed to have a concave and convex surface. For example, the side surfaces of a portion of the region isolation material layer 119P covering the inner surface of the first recess space RS1 and facing the active region 118 may be formed to have a surface including alternating concave and convex portions.

Referring to FIG. 7A to FIG. 7E, a region isolation filling material layer 115P may be disposed on the region isolation material layer 119P. The region isolation filling material layer 115P may be formed to cover the region isolation material layer 119P. The region isolation filling material layer 115P may include oxide. For example, the region isolation filling material layer 115P may include silicon oxide. The region isolation material layer 119P may include a material different from a material of the device isolation material layer 116P and the region isolation filling material layer 115P. The region isolation filling material layer 115P may be formed to have a sufficient thickness to fill both the region isolation trench 115T and the second recess space RS2. The region isolation material layer 119P may be formed to have the fifth width W5 between the active region 118 and the logic active region 117. For example, the fifth width W5 may be less than the first width W1, and may be about 300 nm to about 500 nm.

Referring to FIG. 7A to FIG. 7E and FIG. 8A to FIG. 8E, the region isolation filling layer 115 may be formed by removing a part of the region isolation filling material layer 115P. The removal of the part of the region isolation filling material layer 115P may use the region isolation material layer 119P as an etch stop layer. For example, the region isolation filling layer 115 may be formed through a chemical mechanical polishing (CMP) process removing a part of the region isolation filling material layer 115P and exposing a portion of the region isolation material layer 119P. An upper surface of the region isolation filling layer 115 may be at the same vertical level as the uppermost surface of the region isolation material layer 119P. The upper surface of the region isolation filling layer 115 may be at a higher vertical level than the uppermost surface of the device isolation material layer 116P.

In the present specification, a level or a vertical level refers to a height or a position in the vertical direction (Z direction) with respect to a surface or an upper surface of the substrate 110. That is, being at the same level or at a constant level means a location where the height is the same or constant in the vertical direction (Z direction) with respect to the surface or the upper surface of the substrate 110, and being at a low/high level means a low/high location in the vertical direction (Z direction) with respect to the surface of the substrate 110.

Referring to FIG. 8A to FIG. 8E and FIG. 9A to FIG. 9E, the region isolation structure 119 may be formed by removing a part of the region isolation material layer 119P, wherein the uppermost surface of the device isolation material layer 116P, i.e., an upper surface of a portion of the device isolation material layer 116P covering the plurality of active regions 118 and the plurality of logic active regions 117, is exposed.

The region isolation structure 119 may include the inner region isolation layer 119I, the outer region isolation layer 119O, and the connection region isolation layer 119C. The connection region isolation layer 119C may connect the inner region isolation layer 119I to the outer region isolation layer 119O. Among portions of the region isolation structure 119 disposed between a portion of the device isolation material layer 116P and a portion of the region isolation filling layer 115 that are adjacent in the horizontal direction, the portion of the region isolation structure 119 adjacent to the plurality of active regions 118 may be the inner region isolation layer 119I, the portion of the region isolation structure 119 adjacent to the plurality of logic active regions 117 may be the outer region isolation layer 119O, and the portion of the region isolation structure 119 disposed between a portion of the device isolation material layer 116P and a portion of the region isolation filling layer 115 adjacent in the vertical direction (Z direction) and connecting a lower end portion of the inner region isolation layer 119I and a lower end portion of the outer region isolation layer 119O may be the connection region isolation layer 119C. The inner region isolation layer 119I, the outer region isolation layer 119O, and the connection region isolation layer 119C connecting the inner region isolation layer 119I to the outer region isolation layer 119O may be integrally formed. The region isolation structure 119 may have a U-shaped vertical cross-section between the memory cell region CR and the peripheral region PR. For example, the connection region isolation layer 119C may connect a lower portion of the inner region isolation layer 119I to a lower portion of the outer region isolation layer 119O.

In a process of forming the region isolation structure 119 and the region isolation filling layer 115, a portion of the region isolation material layer 119P disposed between the region isolation filling layer 115 and the device isolation material layer 116P may be removed. For example, an upper part of the region isolation material layer 119P may be thinned and removed in the process of forming the region isolation structure 119 and the region isolation filling layer 115. A region isolation dent 119D may be formed. The region isolation dent 119D may be located in an upper side between a portion of the device isolation material layer 116P and a portion of the region isolation filling layer 115 that are adjacent in the horizontal direction. The region isolation dent 119D may be located on upper sides of the inner region isolation layer 119I and the outer region isolation layer 119O.

Referring to FIG. 10A to FIG. 10E, a plurality of word line trenches 120T may be formed in the substrate 110. The plurality of word line trenches 120T may be formed in the substrate 110 by removing a part of the plurality of active regions 118 and a part of the device isolation material layer 116P. The plurality of word line trenches 120T may extend parallel to each other in the first horizontal direction (X direction) and may each have a line shape crossing the active region 118. The plurality of word line trenches 120T may be disposed at substantially equal intervals in the second horizontal direction (Y direction). In some embodiments, one or more steps may be formed on bottom surfaces of the plurality of word line trenches 120T.

The plurality of word line trenches 120T may extend in the first horizontal direction (X direction) by the extension length EL from an edge of the active region ACT. The edge of the active region ACT may be located at the outermost part of the memory cell region CR in the first horizontal direction (X direction) among the plurality of active regions ACT. The plurality of word lines WL may extend in the first horizontal direction (X direction) by an extension length EL from a proximate end portion of an adjacent active region ACT located at the outermost part of the memory cell region CR in the first horizontal direction (X direction). The extension length EL may have a value smaller than the third width W3 and the plurality of word line trenches 120T may not extend to the region isolation structure 119. Each of the plurality of word line trenches 120T may be spaced apart from the region isolation structure 119 by a gap G1. For example, each of the plurality of word line trenches 120T may be spaced apart from the inner region isolation layer 119I by the gap G1. The sum of the extension length EL and the gap G1 may be the same as the third width W3. Accordingly, the plurality of word line trenches 120T may be spaced apart from the region isolation dent 119D. The plurality of word line trenches 120T may not be affected by the region isolation dent 119D and may be formed to have substantially the same width in the second horizontal direction (Y direction).

Referring to FIG. 10A to FIG. 10E and FIG. 11A to FIG. 11E, a plurality of gate dielectric layers 122, a plurality of word lines 120, and a plurality of buried insulating layers 124 may be formed sequentially in the plurality of word line trenches 120T. For example, the plurality of gate dielectric layers 122 may be disposed on the plurality of word line trenches 120T, the plurality of word lines 120 may be disposed on the plurality of gate dielectric layers 122, and the plurality of buried insulating layers 124 may be disposed on the plurality of word lines 120. The plurality of word lines 120 may form the plurality of word lines WL illustrated in FIG. 3A. The plurality of word lines 120 may extend parallel to each other in the first horizontal direction (X direction) and may each have a line shape crossing the active region 118 and disposed at substantially equal intervals in the second horizontal direction (Y direction). An upper surface of each of the plurality of word lines 120 may be at a lower level than the upper surface of the substrate 110. A bottom surface of each of the plurality of word lines 120 may have an uneven shape, and saddle fin transistors FinFETs may be formed in the plurality of active regions 118.

Each of the plurality of word lines 120 may have a stacked structure of a lower word line layer 120a and an upper word line layer 120b. For example, the lower word line layer 120a may include a metal material, a conductive metal nitride, or a combination thereof. In some embodiments, the lower word line layer 120a may include Titanium (Ti), Titanium Nitride (TiN), Tantalum (Ta), Tantalum Nitride (TaN), Tungsten (W), Tungsten Nitride (WN), Titanium Silicon Nitride (TiSiN), or Tungsten Silicon Nitride (WSiN), or a combination thereof. For example, the upper word line layer 120b may include doped polysilicon. In some embodiments, the lower word line layer 120a may include a core layer and a barrier layer disposed between the core layer and the gate dielectric layer 122.

In some embodiments, before or after forming the plurality of word lines 120, a source region and a drain region may be formed in the plurality of active regions 118. The source region and the drain region may be formed in the plurality of active regions 118 by injecting impurity ions into portions of the active region 118 of the substrate 110 on sides of the plurality of word lines 120.

The gate dielectric layer 122 may include at least one selected from silicon oxide, silicon nitride, silicon oxynitride, oxide/nitride/oxide (ONO), or high-k dielectrics having a higher dielectric constant than silicon oxide. For example, the gate dielectric layer 122 may have a dielectric constant of about 10 to about 25.

An upper surface of each of the plurality of buried insulating layers 124 may be at substantially the same level as the upper surface of the substrate 110. The buried insulating layer 124 may include at least one material selected from silicon oxide, silicon nitride, or silicon oxynitride, or a combination thereof.

In a process of forming the plurality of gate dielectric layers 122, the plurality of word lines 120, and the plurality of buried insulating layers 124, the device isolation layer 116 may be formed by removing a part of the upper side of the device isolation material layer 116P, and a part of the upper side of each of the region isolation structure 119 and the region isolation filling layer 115 may also be removed. The plurality of active regions 118 may be defined by the device isolation layer 116 in the substrate 110 in the memory cell region CR, and the plurality of logic active regions 117 of the substrate 110 may be defined in the peripheral region PR.

In some embodiments, the upper surface of each of the device isolation layer 116, the region isolation structure 119, and the region isolation filling layer 115 may be at the same vertical level to be coplanar. For example, the upper surface of the device isolation layer 116, the upper surface of the inner region isolation layer 119I, the upper surface of the outer region isolation layer 119O, and the upper surface of the region isolation filling layer 115 may be at the same vertical level to be coplanar. A portion of the device isolation layer 116, the region isolation structure 119, and the region isolation filling layer 115 located in the boundary region BDR may be collectively referred to as the boundary structure BDS. The portion of the device isolation layer 116 located in the boundary region BDR may be referred to as a boundary isolation layer. The boundary isolation layer may cover inner and bottom surfaces of the region isolation trench 115T. The boundary isolation layer may cover inner and bottom surfaces of the region isolation trench 115T and may have a U-shaped vertical cross-section.

Referring to FIG. 12A to FIG. 12E, a first insulating layer pattern 112 and a second insulating layer pattern 114 may be formed to cover the device isolation layer 116, the plurality of active regions 118, the plurality of buried insulating layers 124, the boundary structure BDS, and the plurality of logic active regions 117. For example, the first insulating layer pattern 112 and the second insulating layer pattern 114 may include a silicon oxide layer, a silicon nitride layer, a silicon oxynitride layer, or a metal dielectric layer, or a combination thereof. In some embodiments, the first insulating layer pattern 112 and the second insulating layer pattern 114 may be formed by stacking a plurality of insulating layers including the first insulating layer pattern 112 and the second insulating layer pattern 114. In some embodiments, the first insulating layer pattern 112 may include a silicon oxide layer and the second insulating layer pattern 114 may include a silicon oxynitride layer. In some embodiments, the first insulating layer pattern 112 may include a non-metallic dielectric layer and the second insulating layer pattern 114 may include a metallic dielectric layer.

After forming the conductive semiconductor layer 132P on the first insulating layer pattern 112 and the second insulating layer pattern 114, a direct contact hole 134H may be formed through the conductive semiconductor layer 132P and the first insulating layer pattern 112 and the second insulating layer pattern 114. to the direct contact hole 134H may expose the source/drain region in the active region 118. A direct contact conductive layer 134P may be disposed in the direct contact hole 134H. The direct contact conductive layer 134P may be formed to fill the direct contact hole 134H. In some embodiments, the direct contact hole 134H may extend into the active region 118, that is, into the source/drain region. The conductive semiconductor layer 132P may include, for example, doped polysilicon. The direct contact conductive layer 134P may include, for example, doped polysilicon. In some embodiments, the direct contact conductive layer 134P may include an epitaxial silicon layer. In some embodiments, the direct contact conductive layer 134P may include metal or a metal compound that is a conductive material. For example, the direct contact conductive layer 134P may include a metal such as Ti or W, or a conductive material that is a compound of the metal such as Ti and W and a non-metal such as Si, C, B, or N. In some embodiments, the direct contact conductive layer 134P may include TIN, WC, or WSi.

Referring to FIG. 12A to FIG. 12E and FIG. 13A to FIG. 13E, a metallic conductive layer and an insulating capping layer may be sequentially formed. The metallic conductive layer may cover the conductive semiconductor layer 132P and the direct contact conductive layer 134P and may form the bit line structure 140. In some embodiments, the metallic conductive layer may have a stacked structure of a first metallic conductive layer and a second metallic conductive layer. A plurality of bit lines 147 each having a stacked structure of a first metallic conductive pattern 145 and a second metallic conductive pattern 146 may have a line shape and a plurality of insulating capping lines 148 may be formed by etching the first metallic conductive layer and the second metallic conductive layer.

In some embodiments, the first metallic conductive pattern 145 may include titanium nitride (TiN) or TSN (Ti—Si—N) and the second metallic conductive pattern 146 may include tungsten (W) or tungsten silicide (WSix). In some embodiments, the first metallic conductive pattern 145 may function as a diffusion barrier. In some embodiments, the plurality of insulating capping lines 148 may each include a silicon nitride layer.

A bit line 147 and an insulating capping line 148 covering a bit line 147 may form a bit line structure 140. The plurality of bit line structures 140 each including the bit line 147 and the insulating capping line 148 covering the bit line 147 may extend parallel to each other in the second horizontal direction (Y direction) parallel to the surface of the substrate 110. The plurality of bit lines 147 may form the plurality of bit lines BL illustrated in FIG. 3A. In some embodiments, the bit line structure 140 may further include a conductive semiconductor pattern 132 that is a part of the conductive semiconductor layer 132P disposed between the first insulating layer pattern 112 and the second insulating layer pattern 114 and the first metallic conductive pattern 145.

In an etching process of forming the plurality of bit lines 147, by removing a portion of the conductive semiconductor layer 132P that does not vertically overlap the bit line 147 and a portion of the direct contact conductive layer 134P together, a plurality of conductive semiconductor patterns 132 and a plurality of direct contact conductive patterns 134 may be formed. At this time, the first insulating layer pattern 112 and the second insulating layer pattern 114 may function as an etch stop layer in the etching process of forming the plurality of bit lines 147, the plurality of conductive semiconductor patterns 132, and the plurality of direct contact conductive patterns 134. The plurality of direct contact conductive patterns 134 may form the plurality of direct contacts DC illustrated in FIG. 3A. The plurality of bit lines 147 may be electrically connected to the plurality of active regions 118 through the plurality of direct contact conductive patterns 134. The conductive semiconductor pattern 132 may include, for example, doped polysilicon. The direct contact conductive pattern 134 may include doped polysilicon, metal, or a metal compound that is a conductive material. For example, the direct contact conductive pattern 134 may include a metal such as Ti or W, or a conductive material that is a compound of the metal such as Ti or W and a non-metal such as Si, C, B, or N. In some embodiments, the direct contact conductive pattern 134 may include TIN, WC, or WSi.

Both sidewalls of each of the plurality of bit line structures 140 may be covered with an insulating spacer structure 150. The plurality of insulating spacer structures 150 may each include a first insulating spacer 152, a second insulating spacer 154, and a third insulating spacer 156. The second insulating spacer 154 may include a material having a lower dielectric constant than those of the first insulating spacer 152 and the third insulating spacer 156. In some embodiments, the first insulating spacer 152 and the third insulating spacer 156 may include a nitride layer, and the second insulating spacer 154 may include an oxide layer. In some embodiments, the first insulating spacer 152 and the third insulating spacer 156 may include a nitride layer, and the second insulating spacer 154 may include a material having an etch selectivity with respect to the first insulating spacer 152 and the third insulating spacer 156. For example, when the first insulating spacer 152 and the third insulating spacer 156 include a nitride layer, the second insulating spacer 154 include an oxide layer, the first insulating spacer 152 and the third insulating spacer 156 include a nitride layer, the second insulating spacer 154 may be removed in a subsequent process to be an air spacer.

A plurality of buried contact holes 170H may be formed between each of the plurality of bit lines 147. An inner space of each of the plurality of buried contact holes 170H may be limited by the insulating spacer structure 150 covering sidewalls of each of two neighboring bit lines 147 between the two neighboring bit lines 147 among the plurality of bit lines 147, and the active region 118.

The plurality of buried contact holes 170H may be formed by removing the first insulating layer pattern 112 and the second insulating layer pattern 114 and a part of the active region 118, by using the plurality of insulating capping lines 148 and the insulating spacer structure 150 covering both sidewalls of each of the plurality of bit line structures 140 as an etch mask. In some embodiments, the plurality of buried contact holes 170H may be formed to expand a space limited by the active region 118 by first performing an anisotropic etching process of removing the first insulating layer pattern 112 and the second insulating layer pattern 114 and the part of the active region 118, by using the plurality of insulating capping lines 148 and the insulating spacer structure 150 covering both sidewalls of each of the plurality of bit line structures 140 as an etch mask, and then performing an isotropic etching process of further removing another part of the active region 118.

A plurality of gate line structures 140P may be formed on the logic active region 117. In some embodiments, at least one dummy bit line structure 140D may be disposed between the bit line structure 140 and the gate line structure 140P. For example, the at least one dummy bit line structure 140D may extend in the second horizontal direction (Y direction) in the plurality of buried insulating layers 124 covering the plurality of word lines 120 adjacent to the boundary structure BDS.

The gate line structure 140P may include a gate line 147P and an insulating capping line 148 covering the gate line 147P. A plurality of gate lines 147P included in the plurality of gate line structures 140P may be formed together with a plurality of bit lines 147. That is, the gate line 147P may have a stacked structure of a first metallic conductive pattern 145 and a second metallic conductive pattern 146. A gate insulating layer pattern 142 may be disposed between the gate line 147P and the logic active region 117. In some embodiments, the gate line structure 140P may include the conductive semiconductor pattern 132 disposed between the gate insulating layer pattern 142 and the first metallic conductive pattern 145. The plurality of gate lines 147P may form the plurality of gate line patterns GBL illustrated in FIG. 2.

A sidewall of the gate line structure 140P may be covered with a gate insulating spacer 150P. The gate insulating spacer 150P may include, for example, a nitride layer. In some embodiments, the gate insulating spacer 150P may include a single layer, but the present specification is not limited thereto and the gate insulating spacer 150P may have a plurality of stacked structures including a double layer or more.

The dummy bit line structure 140D may extend in parallel with the bit line structure 140 in the second horizontal direction (Y direction) (see FIG. 13E). The dummy bit line structure 140D may have a structure substantially similar to that of the bit line structure 140. The dummy bit line structure 140D may include a dummy bit line 147D including the first metallic conductive pattern 145 and the second metallic conductive pattern 146, and an insulating capping line 148. A sidewall of the dummy bit line structure 140D may be covered by at least one of the insulating spacer structure 150 or the gate insulating spacer 150P.

In some embodiments, a width of the dummy bit line 147D in the first horizontal direction (X direction) may be greater than a horizontal width of the bit line 147. In some embodiments, the width of the dummy bit line 147D in the first horizontal direction (X direction) may be the same as the horizontal width of the bit line 147. In some embodiments, a plurality of dummy bit line structures 140D may be provided, and widths of some of the plurality of dummy bit line structures 140D in the first horizontal direction (X direction) may be greater than the horizontal width of the bit line 147, and widths of the other dummy bit line structures 140D in the first horizontal direction (X direction) may be the same as the horizontal width of the bit line 147.

Referring to FIG. 14A to FIG. 14D, a plurality of buried contacts 170 and a plurality of insulating fences 180 may be formed. The plurality of buried contacts 170 and the plurality of insulating fences 180 may be formed between the plurality of insulating spacer structures 150 covering both sidewalls of each of the plurality of bit line structures 140. The plurality of buried contacts 170 and the plurality of insulating fences 180 may be disposed alternately along between a pair of insulating spacer structures 150 facing each other, that is, in the second horizontal direction (Y direction), among the plurality of insulating spacer structures 150 covering both sidewalls of the plurality of bit line structures 140. For example, the plurality of buried contacts 170 may include polysilicon. For example, the plurality of insulating fences 180 may include a nitride layer.

In some embodiments, the plurality of buried contacts 170 may be disposed in a line in each of the first horizontal direction (X direction) and the second horizontal direction (Y direction). Each of the plurality of buried contacts 170 may extend from the active region 118 in the vertical direction (Z direction), perpendicular to the substrate 110. The plurality of buried contacts 170 may form the plurality of buried contacts BC illustrated in FIG. 3A.

The plurality of buried contacts 170 may be respectively disposed in spaces limited by a plurality of insulating fences 180 and a plurality of insulating spacer structures 150 covering both sidewalls of the plurality of bit line structures 140. The plurality of buried contacts 170 may respectively fill parts of upper sides of the spaces between the plurality of insulating spacer structures 150 covering both sidewalls of the plurality of bit line structures 140.

Levels of upper surfaces of the plurality of buried contacts 170 may be respectively lower than levels of upper surfaces of the plurality of insulating capping lines 148. Upper surfaces of the plurality of insulating fences 180 and the upper surfaces of the plurality of insulating capping lines 148 may be at the same level in the vertical direction (Z direction).

A plurality of landing pad holes 190H may be defined by the plurality of insulating spacer structures 150 and the plurality of insulating fences 180. The plurality of buried contacts 170 may be exposed at bottom surfaces of the plurality of landing pad holes 190H.

In a process of forming the plurality of buried contacts 170 and/or the plurality of insulating fences 180, levels of the upper surfaces of the bit line structure 140, the dummy bit line structure 140D (see FIG. 13E), and the gate line structure 140P (see FIG. 13E) may be lowered by removing parts of upper sides of the insulating capping line 148 included in the bit line structure 140, the dummy bit line structure 140D (see FIG. 13E), and the gate line structure 140P (see FIG. 13E), the insulating spacer structure 150, and the gate insulating spacer 150P (see FIG. 13E).

Referring to FIG. 15A to FIG. 15D, a landing pad material layer may be disposed in the plurality of landing pad holes 190H and may cover the plurality of bit line structures 140. The landing pad material layer is formed to fill the plurality of landing pad holes 190H. In some embodiments, the landing pad material layer may include a conductive barrier layer and a conductive pad material layer on the conductive barrier layer. For example, the conductive barrier layer may include metal, conductive metal nitride, or a combination thereof. In some embodiments, the conductive barrier layer may have a Ti/TiN stacked structure. In some embodiments, the conductive pad material layer may include tungsten (W).

In some embodiments, a metal silicide layer may be formed on the plurality of buried contacts 170 before forming the landing pad material layer. The metal silicide layer may be disposed between the plurality of buried contacts 170 and the landing pad material layer. The metal silicide layer may include cobalt silicide (CoSiₓ), nickel silicide (NiSiₓ), or manganese silicide (MnSiₓ), but is not limited thereto.

A plurality of landing pads 190 may be formed to fill at least some of the plurality of landing pad holes 190H by removing a part of the landing pad material layer. The plurality of landing pads 190 may extend onto the plurality of bit line structures 140, and may be separated from each other by a recess portion 190R.

The plurality of landing pads 190 may be spaced apart from each other with the recess portion 190R disposed therebetween. The plurality of landing pads 190 may be respectively disposed on the plurality of buried contacts 170 and may extend onto the plurality of bit line structures 140. In some embodiments, the plurality of landing pads 190 may respectively extend onto the plurality of bit lines 147. The plurality of landing pads 190 may be respectively disposed on the plurality of buried contacts 170, and the plurality of buried contacts 170 and the plurality of landing pads 190 that correspond to each other may be electrically connected to each other. The buried contact 170 and the landing pad 190 that correspond to each other may be referred to as a contact plug. The plurality of landing pads 190 may be connected to the active region 118 through the plurality of buried contacts 170. The plurality of landing pads 190 may form the plurality of landing pads LP illustrated in FIG. 3A.

The buried contact 170 may be disposed between adjacent bit line structures 140, and the landing pad 190 may extend from between the adjacent bit line structures 140 onto a bit line structure 140 with the buried contact 170 disposed therebetween.

Referring to FIG. 16A to FIG. 16E, an insulating structure 195 may be formed to fill the recess portion 190R. In some embodiments, the insulating structure 195 may include an interlayer insulating layer and an etch stop layer. For example, the interlayer insulating layer may include oxide, and the etch stop layer may include nitride. In FIG. 16A and FIG. 16C, an upper surface of the insulating structure 195 and an upper surface of the landing pad 190 may be located at the same level, but are not limited thereto.

A plurality of lower electrodes 210 respectively connected to the plurality of landing pads 190 may be formed. The plurality of lower electrodes 210 may be electrically connected to the plurality of landing pads 190, respectively. Each of the plurality of lower electrodes 210 may have a pillar shape, and may have a circular horizontal cross-section, but is not limited thereto. In some embodiments, each of the plurality of lower electrodes 210 may have a cylinder shape with a closed lower portion. In some embodiments, the plurality of lower electrodes 210 may be arranged in a zigzag form disposed in a honeycomb shape in the first horizontal direction (X direction) or the second horizontal direction (Y direction). In some embodiments, the plurality of lower electrodes 210 may be disposed in a matrix form disposed in a line in each of the first horizontal direction (X direction) and the second horizontal direction (Y direction). The plurality of lower electrodes 210 may include, for example, a metal doped with an impurity, such as silicon, tungsten, or copper, or a conductive metal compound such as titanium nitride. The semiconductor memory device 1 may be formed by sequentially forming a capacitor dielectric layer 220 and an upper electrode 230 on the plurality of lower electrodes 210. That is, the capacitor dielectric layer 220 may be disposed on the plurality of lower electrodes 210, and the upper electrode 230 may be disposed on the capacitor dielectric layer 220. The capacitor dielectric layer 220 and the upper electrode 230 on the plurality of lower electrodes 210 may form a plurality of capacitor structures 200. The capacitor dielectric layer 220 may conformally cover surfaces of the plurality of lower electrodes 210. In some embodiments, the capacitor dielectric layer 220 may be formed integrally to cover the plurality of lower electrodes 210 together in a certain region, for example, one memory cell region CR (FIG. 3A).

The capacitor dielectric layer 220 may include, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO), PZT(Pb,Zr,Ti)O), (Pb,La)(Zr,Ti)O, Ba(Zr,Ti)O, or Sr(Zr,Ti)O, or a combination thereof.

The upper electrode 230 may include, for example, W, Ru, RuO, Pt, PtO, Ir, IrO, SRO(SrRuO), BSRO((Ba,Sr)RuO), CRO(CaRuO), BaRuO, La(Sr,Co)O, etc. In some embodiments, the upper electrode 230 may include a metal material. For example, the upper electrode 230 may include W.

A charge insulating layer 172 and a cover insulating layer 174 may be formed in the peripheral region PR and the boundary region BDR. The charge insulating layer 172 and the cover insulating layer 174 may be formed in the peripheral region PR and the boundary region BDR before forming the plurality of capacitor structures 200.

The charge insulating layer 172 may be formed on the first insulating layer pattern 112 and the second insulating layer pattern 114 covering the boundary structure BDS between the plurality of gate line structures 140P and the at least one dummy bit line structure 140D. In some embodiments, the charge insulating layer 172 may include oxide.

In a process of forming the plurality of buried contacts 170 and/or the plurality of insulating fences 180, the levels of the upper surfaces of the bit line structure 140, the dummy bit line structure 140D, and the gate line structure 140P may be lowered by removing parts of the upper sides of the insulating capping line 148 included in the bit line structure 140, the dummy bit line structure 140D, and the gate line structure 140P, the insulating spacer structure 150, and the gate insulating spacer 150P. An upper surface of the charge insulating layer 172, an upper surface of the gate line structure 140P, and the dummy bit line structure 140D may be at the same vertical level to be coplanar.

A cover insulating layer 174 may be formed on the charge insulating layer 172, the gate line structure 140P, and the dummy bit line structure 140D. In some embodiments, the cover insulating layer 174 may include oxide. In some embodiments, an upper surface of the cover insulating layer 174 may be at the same or similar vertical level as the upper surface of the insulating structure 195 and the upper surface of the landing pad 190.

After forming the plurality of capacitor structures 200, a buried insulating layer 250 covering the cover insulating layer 174 may be formed in the peripheral region PR and boundary region BDR. The buried insulating layer 250 may include, for example, an oxide layer or an ultra-low K (ULK) layer. The oxide layer may include any one layer selected from a BoroPhosphoSilicate Glass (BPSG) layer, a PhosphoSilicate Glass (PSG) layer, a BoroSilicate Glass (BSG) layer, an Un-doped Silicate Glass (USG) layer, a Tetra Ethyle Ortho Silicate (TEOS) layer, or a high density plasma (HDP) layer. The ULK layer may include, for example, any one layer selected from a SiOC layer and a SiCOH layer having an ultra-low dielectric constant K of about 2.2 to about 2.4. In some embodiments, the upper surface of the buried insulating layer 250 and the upper electrode 230 may be at the same or similar vertical level.

The semiconductor memory device 1 may include the memory cell region CR, the peripheral region PR, and the boundary region BDR between the memory cell region CR and the peripheral region PR, and may include the substrate 110 including the plurality of active regions 118 and the plurality of logic active regions 117 defined by the device isolation layer 116 in the memory cell region CR and the peripheral region PR, the boundary structure BDS filling the region isolation trench 115T of the substrate 110 in the boundary region BDR, the plurality of gate dielectric layers 122, the plurality of word lines 120, and the plurality of buried insulating layers 124 sequentially formed inside the plurality of word line trenches 120T crossing the plurality of active regions 118 in the substrate 110, the device isolation layer 116, the plurality of active regions 118, the plurality of buried insulating layers 124, the first insulating layer patterns 112 and the second insulating layer patterns 114 covering the boundary structure BDS, the plurality of bit line structures 140 on the first insulating layer patterns 112 and the second insulating layer patterns 114 in the memory cell region CR, the plurality of insulating spacer structures 150 covering both sidewalls of the plurality of bit line structures 140, the plurality of gate line structures 140P on the plurality of logic active regions 117, the plurality of gate insulating spacers 150P covering both sidewalls of the plurality of gate line structures 140P, the plurality of buried contacts 170 filling the lower parts of the spaces limited by the plurality of insulating fences 180 and the plurality of insulating spacer structures 150 and connected to the plurality of active regions 118 and the plurality of landing pads 190 filling the upper parts of the spaces and extending to the upper part of the bit line structure 140, and the plurality of capacitor structures 200 including the plurality of lower electrodes 210 connected to the plurality of landing pads 190, the capacitor dielectric layer 220, and the upper electrode 230.

The device isolation layer 116 may be formed over each of the memory cell region CR, the peripheral region PR, and the boundary region BDR. A portion of the device isolation layer 116 formed in the memory cell region CR may define the plurality of active regions 118, a portion of the device isolation layer 116 formed in the peripheral region PR may define the plurality of logic active regions 117, and a portion of the device isolation layer 116 formed in the boundary region BDR may be a part of the boundary structure BDS. The portion of the device isolation layer 116 formed in the memory cell region CR may be referred to as a cell device isolation layer, the portion of the device isolation layer 116 formed in the peripheral region PR may be referred to as a logic device isolation layer, and the portion of the device isolation layer 116 formed in the boundary region BDR may be referred to as a boundary isolation layer.

The boundary structure BDS may include the region isolation structure 119, the region isolation filling layer 115, and a portion of the device isolation layer 116. The portion of the device isolation layer 116 formed in the boundary region BDR, that is, the boundary isolation layer, may have a U-shaped vertical cross-section defining the first recess space RS1 between the memory cell region CR and the peripheral region PR. The region isolation structure 119 may have a U-shaped vertical cross-section defining the second recess space RS2 between the memory cell region CR and the peripheral region PR. The region isolation structure 119 may be disposed in the boundary isolation layer having the U-shaped vertical cross-section and may fill a part of the first recess space RS1. The region isolation filling layer 115 may fill the second recess space RS2.

The region isolation structure 119 may include the inner region isolation layer 119I, the outer region isolation layer 119O, and the connection region isolation layer 119C connecting the inner region isolation layer 119I to the outer region isolation layer 119O. The inner region isolation layer 119I, the outer region isolation layer 119O, and the connection region isolation layer 119C connecting the inner region isolation layer 119I to the outer region isolation layer 119O may be integrally formed.

The plurality of active regions 118 and the plurality of logic active regions 117 may be spaced apart from each other by the first width W1. For example, the boundary structure BDS located between the active region 118 located at the outermost part of the memory cell region CR and the logic active region 117 located at the outermost part of the peripheral region PR which are adjacent to each other may have the first width W1. The active region 118 may be disposed as a column arranged in a diagonal direction with respect to the first horizontal direction (X direction) and the second horizontal direction (Y direction), and the active region 118 located at the outermost part of the memory cell region CR may include an end portion of the active region proximate to the boundary structure BDS. The first width W1 may be measured between the proximate end portion of the active region 118 and the logic active region 117.

The logic active region 117 and the outer region isolation layer 119O of the region isolation structure 119 may be spaced apart from each other by the second width W2. For example, a portion of the cell device isolation layer located between the logic active region 117 located at the outermost part of the peripheral region PR and the outer region isolation layer 119O of the region isolation structure 119 may have the second width W2. The active region 118 and the inner region isolation layer 119I of the region isolation structure 119 may be spaced apart from each other by the third width W3. For example, a portion of the cell device isolation layer located between the outermost active region 118 of the memory cell region CR and the inner region isolation layer 119I of the region isolation structure 119 may have the third width W3. The second width W2 and the third width W3 may have substantially the same width.

The region isolation structure 119 may have the fourth width W4. For example, each of the inner region isolation layer 119I and the outer region isolation layer 119O of the region isolation structure 119 may have substantially the same fourth width W4. In some embodiments, the second width W2 and the third width W3 may be about three times or more greater than the fourth width W4. The region isolation filling layer 115 may have the fifth width W5. For example, the region isolation filling layer 115 between the inner region isolation layer 119I and the outer region isolation layer 119O may have the fifth width W5. The fourth width W4 may be less than each of the second width W2 and the third width W3, each of the second width W2 and the third width W3 may be less than the fifth width W5, and the fifth width W5 may be less than the first width W1.

Each of the plurality of active regions 118 may have the first length L1 (see FIG. 3B) in a major axis direction and the second length L2 (see FIG. 3B) in a minor axis direction. Among the plurality of active regions 118, active regions 118 adjacent to each other in the minor axis direction of the active region 118 may be spaced apart from each other by the sixth width W6 (see FIG. 3B), and active regions 118 adjacent to each other in the major axis direction of the active region 118 may be spaced apart from each other by the seventh width W7 (see FIG. 3B). For example, among the plurality of active regions 118, a portion of the cell device isolation layer located between the active regions 118 adjacent to each other in the minor axis direction of the active region 118 may have the sixth width W6 (see FIG. 3B), and a portion of the cell device isolation layer located between the active regions 118 adjacent to each other in the major axis direction of the active region 118 may have the seventh width W7 (see FIG. 3B). The first length L1 may have a value greater than about five times or more the second length L2. The sixth width W6 may have a value greater than the second length L2 and less than the seventh width W7. The fourth width W4 may have a value greater than the first length L1.

The plurality of word lines 120 may further extend in the first horizontal direction (X direction) by the extension length EL from an edge of the active region 118. The edge of the active region 118 may be located at the outermost part of the memory cell region CR in the first horizontal direction (X direction) among the plurality of active regions 118. The extension length EL may have a value less than the third width W3. An end of each of the plurality of word lines 120 facing the outermost part of the memory cell region CR may be spaced apart from the region isolation structure 119 by the gap G1. For example, a portion of the boundary isolation layer disposed between an end of each of the plurality of word lines 120 facing the outermost part of the memory cell region CR and the region isolation structure 119 may have a width equal to the gap G1. The sum of the extension length EL and the gap G1 may be the same as the third width W3. Accordingly, the plurality of word lines 120 and the region isolation structure 119 may not overlap each other in the vertical direction (Z direction), and the plurality of word lines WL and the region isolation structure 119 may be spaced apart from each other.

The semiconductor memory device 1 according to the inventive concept may be formed having a portion of the region isolation structure 119 remaining in the boundary region BDR after the region isolation structure 119 has been used as the etch stop layer in the process of forming the device isolation layer 116, and the region isolation structure 119 does not overlap the plurality of word line trenches 120T (see FIG. 10B to FIG. 10E) filled with the plurality of word lines 120 in the vertical direction (Z direction). Accordingly, the region isolation dent 119D (see FIG. 9E) may not affect the etching process for forming the plurality of word line trenches 120T, the plurality of word line trenches 120T may be formed to have substantially the same width in the second horizontal direction (Y direction), and the plurality of word lines 120 formed in the plurality of word line trenches 120T may also be formed to have substantially the same width, wherein the plurality of word lines 120 may not be disconnected. Accordingly, the semiconductor memory device 1 according to the inventive concept may be formed to have a high degree of integration with reduced or no defects, and the semiconductor memory device 1 may have an improved operational reliability.

While the inventive concept has been particularly shown and described with reference to embodiments thereof, it will be understood that various changes in form and details may be made therein without departing from the spirit and scope of the following claims.

What is claimed is:

1. A semiconductor memory device comprising:
a substrate comprising a memory cell region in which a plurality of active regions are defined, a peripheral region in which at least one logic active region is defined, and a boundary region comprising a region isolation trench between the memory cell region and the peripheral region;
a boundary structure comprising a boundary isolation layer, a region isolation structure, and a region isolation filling layer sequentially disposed in the region isolation trench; and
a word line extending across the plurality of active regions in the memory cell region,
wherein among the plurality of active regions, an active region located at an outermost part of the memory cell region and the region isolation structure are spaced apart from each other by a first width, and
the word line extends by an extension length less than the first width from the active region located at the outermost part of the memory cell region towards the region isolation structure.

2. The semiconductor memory device of claim 1, wherein the region isolation structure has a U-shaped vertical cross-section between the memory cell region and the peripheral region.

3. The semiconductor memory device of claim 2, wherein the region isolation structure comprises:
an inner region isolation layer disposed between a first portion of the boundary isolation layer and a first portion of the region isolation filling layer which are adjacent to each other in a horizontal direction and adjacent to the plurality of active regions;
an outer region isolation layer adjacent to the at least one logic active region; and
a connection region isolation layer disposed between a second portion of the boundary isolation layer and a second portion of the region isolation filling layer which are adjacent to each other in a vertical direction and connecting a lower end portion of the inner region isolation layer and a lower end portion of the outer region isolation layer.

4. The semiconductor memory device of claim 3, wherein
the inner region isolation layer is adjacent to the memory cell region and extends along an edge of the memory cell region in a plan view to surround the memory cell region, and
the outer region isolation layer extends along a periphery of the inner region isolation layer in the plan view to surround the inner region isolation layer.

5. The semiconductor memory device of claim 4, wherein
the inner region isolation layer extends wavily in the plan view, and
the outer region isolation layer extends linearly in the plan view.

6. The semiconductor memory device of claim 3, wherein a second width of each of the inner region isolation layer and the outer region isolation layer is less than a third width of the boundary isolation layer.

7. The semiconductor memory device of claim 6, wherein the second width is greater than a length of each of the plurality of active regions in a major axis direction of the plurality of active regions.

8. The semiconductor memory device of claim 1, wherein
the boundary isolation layer covers an inner surface and a bottom surface of the region isolation trench and defines a first recess space,
the region isolation structure covers an inner surface and a bottom surface of the first recess space and defines a second recess space, and
the region isolation filling layer is disposed in the second recess space.

9. The semiconductor memory device of claim 8, wherein the region isolation structure includes a material different from a material of each of the boundary isolation layer and the region isolation filling layer.

10. The semiconductor memory device of claim 9, wherein the region isolation structure includes nitride, and each of the boundary isolation layer and the region isolation filling layer includes oxide.

11. A semiconductor memory device comprising:
a substrate comprising a memory cell region in which a plurality of active regions are defined, a peripheral region in which at least one logic active region is defined, and a boundary region comprising a region isolation trench between the memory cell region and the peripheral region;
a boundary structure comprising a boundary isolation layer, a region isolation structure, and a region isolation filling layer sequentially disposed in the region isolation trench, and surrounding the memory cell region in a plan view;
a plurality of word lines extending in a first horizontal direction across the plurality of active regions in the memory cell region;
a plurality of bit lines respectively disposed on the plurality of active regions and extending in a second horizontal direction crossing the first horizontal direction; and
a gate line disposed on the at least one logic active region,
wherein the region isolation structure and the plurality of word lines are spaced apart from each other in the first horizontal direction and the second horizontal direction.

12. The semiconductor memory device of claim 11, wherein the region isolation structure and the plurality of word lines do not overlap each other in a vertical direction.

13. The semiconductor memory device of claim 11, wherein the region isolation structure comprises:
an inner region isolation layer disposed between a first portion of the boundary isolation layer and a first portion of the region isolation filling layer which are adjacent to each other in a horizontal direction, adjacent to the memory cell region in a plan view, and extending along an edge of the memory cell region;
an outer region isolation layer disposed between a second portion of the boundary isolation layer and a second portion of the region isolation filling layer which are adjacent to each other in the horizontal direction, spaced apart from the inner region isolation layer in a plan view, and extending along a periphery of the inner region isolation layer; and
a connection region isolation layer disposed between a third portion of the boundary isolation layer and a third portion of the region isolation filling layer which are adjacent to each other in a vertical direction and connecting a lower end portion of the inner region isolation layer and a lower end portion of the outer region isolation layer.

14. The semiconductor memory device of claim 13, wherein side surfaces of the inner region isolation layer facing the memory cell region and the outer region isolation layer include concave portions and convex portions, and
wherein side surfaces of the outer region isolation layer facing the inner region isolation layer and the peripheral region are flat surfaces.

15. The semiconductor memory device of claim 13, wherein
each of the plurality of active regions has a first length in a major axis direction and a second length that is less than the first length in a minor axis direction,
among the plurality of active regions, active regions adjacent in the minor axis direction are spaced apart from each other by a first width, and active regions adjacent in the major axis direction are spaced apart from each other by a second width greater than the first width, and
a third width of each of the inner region isolation layer and the outer region isolation layer is greater than each of the first length and the second width.

16. The semiconductor memory device of claim 11, wherein an uppermost surface of the boundary isolation layer, an uppermost surface of the region isolation structure, and an uppermost surface of the region isolation filling layer are at a same vertical level to be coplanar.

17. The semiconductor memory device of claim 11, wherein each of the boundary isolation layer and the region isolation structure has a U-shaped vertical cross-section disposed between the memory cell region and the peripheral region.

18. A semiconductor memory device comprising:
a substrate comprising a memory cell region in which a plurality of active regions are defined, a peripheral region in which at least one logic active region is defined, and a boundary region comprising a region isolation trench between the memory cell region and the peripheral region;
a boundary structure comprising a boundary isolation layer, a region isolation structure, and a region isolation filling layer sequentially disposed in the region isolation trench and surrounding the memory cell region in a plan view, the boundary isolation layer comprising oxide and having a U-shaped vertical cross-section, the region isolation structure comprising nitride and disposed on the boundary isolation layer to have a U-shaped vertical cross-section between the memory cell region and the peripheral region, and the region isolation filling layer comprising oxide and disposed on the region isolation structure;
a plurality of word lines extending in a first horizontal direction across the plurality of active regions in the memory cell region;
a plurality of bit lines respectively disposed on the plurality of active regions and extending in a second horizontal direction substantially orthogonal to the first horizontal direction;
a gate line disposed on the at least one logic active region;
a plurality of buried contacts respectively disposed between the plurality of bit lines and connected to the plurality of active regions;
a plurality of landing pads respectively disposed on the plurality of buried contacts between the plurality of bit lines and extending onto the plurality of bit lines; and
a plurality of capacitor structures comprising a plurality of lower electrodes respectively connected to the plurality of landing pads, an upper electrode, and a capacitor dielectric layer disposed between the plurality of lower electrodes and the upper electrode,
wherein the region isolation structure and the plurality of word lines are spaced apart from each other in the plan view.

19. The semiconductor memory device of claim 18, wherein the region isolation structure comprises:
an inner region isolation layer disposed between a first portion of the boundary isolation layer and a first portion of the region isolation filling layer which are adjacent to each other in a horizontal direction, adjacent to the memory cell region in the plan view, and extending along an edge of the memory cell region;
an outer region isolation layer disposed between a second portion of the boundary isolation layer and a second portion of the region isolation filling layer which are adjacent to each other in the horizontal direction, spaced apart from the inner region isolation layer in the plan view, and extending along a periphery of the inner region isolation layer; and
a connection region isolation layer disposed between a third portion of the boundary isolation layer and a third portion of the region isolation filling layer which are adjacent to each other in a vertical direction and connecting a lower end portion of the inner region isolation layer and a lower end portion of the outer region isolation layer,
wherein side surfaces of the inner region isolation layer facing the memory cell region and the outer region isolation layer include concave portions and convex portions,
the inner region isolation layer extends wavily in the plan view, and
the outer region isolation layer extends linearly in the plan view.

20. The semiconductor memory device of claim 19, wherein a width of each of the inner region isolation layer and the outer region isolation layer is less than a width of the boundary isolation layer and greater than a length of each of the plurality of active regions in a major axis direction of the plurality of active regions.
